(19) United States
(12) Patent Application Publication
(10) Pub. No.: US 2024/0431124 A1
(43) Pub. Date: Dec. 26, 2024

(54) MULTIVALENT ORGANIC SALTS FOR PHOTOVOLTAICS

(71) Applicant: Board of Trustees of Michigan State University, East Lansing, MI (US)

(72) Inventors: Richard Royal LUNT, III, Williamston, MI (US); Matthew BATES, Hillsboro, OR (US)

(73) Assignee: Board of Trustees of Michigan State University, East Lansing, MI (US)

(21) Appl. No.: 18/760,533

(22) Filed: Jul. 1, 2024

Related U.S. Application Data
(63) Continuation of application No. PCT/US2023/027919, filed on Jul. 17, 2023.
(60) Provisional application No. 63/389,875, filed on Jul. 16, 2022.

(51) Int. Cl. H10K 30/20; H10K 30/50; H10K 85/20; H10K 85/60

(52) U.S. Cl. CPC H10K 30/20; H10K 30/50; H10K 85/211; H10K 85/652

(57) ABSTRACT

A photovoltaic device includes a first electrode, a second electrode, and a photoactive layer between the first electrode and the second electrode. The photoactive layer includes a first organic salt. The first organic salt includes a photoactive ion and a counterion. The photoactive ion has a first valence selected from the group consisting of: 1+, 2+, 3+, 4+, 5+, 6+, 7+, 8+, 1−, 2−, 3−, 4−, 5−, 6−, 7−, or 8−. The counterion has a second valence selected from the group consisting of: 1+, 2+, 3+, 4+, 5+, 6+, 7+, 8+, 2−, 3−, 4−, 5−, 6−, 7−, or 8−. A sum of a magnitude of the first valence and a magnitude of the second valence is greater than or equal to 3. A net charge of the first organic salt is zero.

### CROSS-REFERENCE TO RELATED APPLICATIONS

This application is a continuation of PCT Patent application Serial No. PCT/US2023/027919, filed on Jul. 17, 2023, which claims the benefit of U.S. Provisional patent application Ser. No. 63/389,875, filed on Jul. 16, 2022. This application is related to U.S. patent application Ser. No. 18/222,944 and PCT Patent application Serial No. PCT/US2023/027933, both filed simultaneously on Jul. 17, 2023. The entire disclosures of each of the above applications are incorporated herein by reference. The entire disclosures of the above applications are incorporated hereby by reference.

### FIELD

The present disclosure relates to multivalent organic salts for photovoltaics.

### BACKGROUND

This section provides background information related to the present disclosure which is not necessarily prior art.

Organic small molecules are suitable in electronics, imaging, optoelectronics, and therapeutics due to their strong molecular extinction coefficients, processability, tunable absorption bands, and high fluorescence quantum yields. In optoelectronics, organic small molecules have given rise to organic photovoltaics (OPVs) and transparent photovoltaics (TPVs) in non-fullerene all-small molecule devices or paired with polymeric donors in bulk heterojunction solar cells. All-small molecule OPVs have achieved over 17% power conversion efficiency (PCE), and offer yet unrealized potential for industrial scale TPVs.

Organic salts are a class of organic small molecules composed of an ionic chromophore and a counterion. Organic salts have been employed in a range of applications including photodetectors, OPVs, transparent luminescent solar concentrators, TPVs, fluorescent imaging, and photodynamic therapy. Chromophores within organic salts can include cyanine dyes, categorized in part by the length of the conjugated bridge, most commonly three (trimethine), five (pentamethine), or seven (heptamethine) atoms long. The bridge length and additional conjugation on the ends of the cyanine determine the location of the main absorption band, which can be tuned through the visible spectrum to deep into the near-infrared (NIR).

To date, most demonstrations of organic salts in OPVs and TPVs have focused on a cationic chromophore paired with various counterions, which are long thought to have reduced or minimal impact on the device performance. A range of counterion effects have been shown, including that counterion exchange can tune the highest occupied molecular orbital (HOMO) by over 1 eV, increase exciton diffusion lengths, extend device lifetimes to greater than seven years under standard illumination, and increase molecular order in a neat film to improve device performance. The best organic salt devices to date have achieved 4.3% PCE in tandem OPVs and 2.2% in single-junction TPVs, well below the realistic limit for TPVs. Devices are restricted by short exciton diffusion lengths (<10 nm) that limit devices to thin layers of organic salt, and a general inability to form a stable bulk heterojunction (BHJ), as only two have been shown to date, achieving less than 0.4% PCE. Exciton diffusion has only recently been studied in organic salt PVs, while charge transport has been studied in other electronic devices, including dye-sensitized solar cells, inorganic PVs, photodetectors, and phthalocyanine-fullerene PVs. Charge transport in organic salts has only been explored in the form of long excited-state lifetimes and hole mobilities for cationic chromophores.

Anionic cyanines in organic salts have been studied for light-based applications, but have seen very little use in OPVs and TPVs. One study fabricated simplified dye-sensitized solar cells with anionic trimethine cyanines that demonstrated 1-2% external quantum efficiency (EQE) at the peak salt absorption wavelength. Another study synthesized an organic salt consisting of two cyanine dyes, one cationic and one anionic, and deployed the salt as the donor material in a BHJ OPV with 0.37% PCE and 11% peak EQE from the organic salt. Control devices with an anionic heptamethine based organic salt achieved 0.07% PCE and approximately 1% peak EQE from the salt.

### SUMMARY

This section provides a general summary of the disclosure, and is not a comprehensive disclosure of its full scope or all of its features.

Small bandgap organic compounds with absorption in the near-infrared are exciting materials for a variety of applications ranging from light harvesters in photovoltaics to active agents in photodynamic therapy. Organic salts, a class of small molecule organic compounds comprised of an ionic chromophore and a counterion, have been used in opaque and transparent photovoltaics, primarily as donor materials in bilayer architectures. They possess excellent molecular extinction coefficients with near-infrared selective absorption, adjustable bandgaps, and tunable energy levels. To approach organic salt photovoltaics from a new perspective, devices are fabricated with an unexplored group of anionic salts comprised of a near-infrared absorbing chromophore paired with a varying number of cationic counterions. Different donor and acceptor decay trends in external quantum efficiencies are observed, which facilitate separating and independently quantifying exciton diffusion and charge transfer for each salt. Increased charge character on the chromophore greatly improves hole transport, as anions with a net-3 charge have charge collection lengths greater than four times those of corresponding singly charged chromophores. This presents an interesting platform for the independent quantification of exciton diffusion and charge transport of an active material in a single photovoltaic device and demonstration of the important role of charge on the chromophore. The dependence of charge transport capabilities on charge character of the chromophore will be a useful tool in the design of future organic salts to engineer materials for higher efficiency transparent photovoltaics.

The examples herein involve fabrication of devices from four new salts including an anionic heptamethine cyanine chromophore and one or more sodium cations. This selection of materials allowed us to independently demonstrate the effects of increased conjugation and charge character in the chromophore on device performance and underlying processes such as exciton diffusion and charge transfer. The organic salts are paired with fullerene to create devices with two isolated absorption regimes and distinct thickness dependent performance decay trends that facilitate quantification of exciton diffusion and charge transfer for each salt. Transfer matrix optical modeling is used to fit thickness-dependent data for characteristic lengths of exciton diffusion and charge collection, and demonstrate the impact that charge character on the chromophore has on each process. Carrier mobility and lifetime of the organic salts are characterized to elucidate the origin of improved charge transfer. The Examples herein demonstrate the nature of fundamental charge transfer processes in these materials and a platform from which to characterize exciton diffusion and charge transfer from a single device.

At least one example embodiment relates to a photovoltaic device.

In at least one example embodiment, the photovoltaic device includes a first electrode, a second electrode, and a photoactive layer between the first electrode and the second electrode. The photoactive layer includes a first organic salt. The first organic salt includes a photoactive ion and a counterion. The photoactive ion has a first valence selected from the group consisting of: 1+, 2+, 3+, 4+, 5+, 6+, 7+, 8+, 1−, 2−, 3−, 4−, 5−, 6−, 7−, or 8−. The counterion has a second valence selected from the group consisting of: 1+, 2+, 3+, 4+, 5+, 6+, 7+, 8+, 2−, 3−, 4−, 5−, 6−, 7−, or 8−. A sum of a magnitude of the first valence and a magnitude of the second valence is greater than or equal to 3. A net charge of the first organic salt is zero.

In at least one example embodiment, the sum of the magnitude of the first valence and the second valence is greater than or equal to 4.

In at least one example embodiment, the photoactive ion is a photoactive cation and the counterion is an anion.

In at least one example embodiment, the anion is a tetrel, a chalcogen, a halogen, a transition metal, organic anion, a tetrahedral anion, an octahedral anion, or any combination thereof.

In at least one example embodiment, the photoactive ion is a photoactive anion and the counterion is a cation.

In at least one example embodiment, the cation is an alkali metal, an alkaline earth metal, a transition metal, a triel, a tetral, a pnictogen, an organic cation, or any combination thereof.

In at least one example embodiment, the photoactive ion is a polymethine cyanine salt.

In at least one example embodiment, the first organic salt has an exciton diffusion length ranging from 10 nm to 300 nm.

In at least one example embodiment, the first organic salt has a charge collection length ranging from 10 nm to 10,000 nm.

In at least one example embodiment, the first organic salt has a bandgap of less than or equal to 2 eV.

In at least one example embodiment, the entire device has an average visible transmittance (AVT) of greater than 50%.

In at least one example embodiment, the device is opaque.

In at least one example embodiment, the device has a power conversion efficiency of greater than 0.5%.

In at least one example embodiment, the device has a maximum external quantum efficiency (EQE) of greater than or equal to 2%.

In at least one example embodiment, the photoactive layer includes a donor layer, and an acceptor layer.

In at least one example embodiment, the donor layer is neat and the acceptor layer is neat.

In at least one example embodiment, the donor layer includes the first organic salt.

In at least one example embodiment, the donor layer is amorphous. In at least one example embodiment, the donor layer is crystalline or nanocrystalline.

In at least one example embodiment, the donor layer further includes a second organic salt.

In at least one example embodiment, the second organic salt includes a second photoactive ion and a second counterion. The second photoactive ion has a third valence selected from the group consisting of: 1+, 2+, 3+, 4+, 5+, 6+, 7+, 8+, 1−, 2−, 3−, 4−, 5−, 6−, 7−, or 8−. The second counterion has a fourth valence selected from the group consisting of: 1+, 2+, 3+, 4+, 5+, 6+, 7+, 8+, 2−, 3−, 4−, 5−, 6−, 7−, or 8−. A sum of a magnitude of the third valence and a magnitude of the fourth valence is greater than or equal to 3. An overall charge of the second organic salt is zero.

In at least one example embodiment, the acceptor layer includes a fullerene.

In at least one example embodiment, the acceptor layer includes a second organic salt.

In at least one example embodiment, the second organic salt includes a second photoactive ion and a second counterion. The second photoactive ion has a third valence selected from the group consisting of: 1+, 2+, 3+, 4+, 5+, 6+, 7+, 8+, 1−, 2−, 3−, 4−, 5−, 6−, 7−, or 8−. The second counterion has a fourth valence selected from the group consisting of: 1+, 2+, 3+, 4+, 5+, 6+, 7+, 8+, 2−, 3−, 4−, 5−, 6−, 7−, or 8−. A sum of a magnitude of the third valence and a magnitude of the fourth valence is greater than or equal to 3. An overall charge of the second organic salt is zero.

In at least one example embodiment, the donor layer defines a first thickness ranging from 5 nm to 200 nm. The acceptor layer defines a second thickness ranging from 5 nm to 200 nm.

In at least one example embodiment, the donor layer has a peak absorption at a first wavelength of greater than or equal to 650 nm. The acceptor layer has a peak absorption at a second wavelength of greater than or equal to 650 nm.

In at least one example embodiment, the device has a fill factor of greater than or equal to 0.45.

In at least one example embodiment, the device has an absorption of greater than 50% at a wavelength of greater than or equal to 300 nm to less than or equal to 1,200 nm.

In at least one example embodiment, the device has an open circuit voltage of greater than 50% of the excitonic voltage limit.

In at least one example embodiment, the magnitude of the valence of the photoactive ion is greater than the magnitude of the counterion.

In at least one example embodiment, the counterion is a photoactive ion.

At least one example embodiment relates to a photoactive device.

In at least one example embodiment, the photoactive device includes a first electrode, a second electrode, and a photoactive layer between the first electrode and the second electrode. The photoactive layer includes an organic salt having the formula C_{y}^{x+}Aₓ^{y-}, wherein C is a cation, A is an anion, x=1+, 2+, 3+, 4+, 5+, 6+, 7+, or 8+, y=1−, 2−, 3−, 4−, 5−, 6−, 7−, or 8−, and (|x|+|y|)≥3.

At least one example embodiment relates to a method of preparing a photoactive layer for a photovoltaic (PV) device.

In at least one example embodiment, the method includes preparing a modified photoactive ion by increasing an overall valence of a photoactive ion. The method further includes preparing a multivalent neutral organic salt according to the formula C_{y}^{x+}Aₓ^{y-}, where C is a cation, A is an anion, x=1+, 2+, 3+, 4+, 5+, 6+, 7+, or 8+, y=1−, 2−, 3−, 4−, 5−, 6−, 7−, or 8−, and (|x|+|y|)≥3. The method further includes incorporating the multivalent neutral organic salt into the photoactive layer of the PV device.

In at least one example embodiment, the preparing the modified photoactive ion includes adding charged groups to the photoactive ion.

In at least one example embodiment, the charged groups are selected from sulfonate, dinitrile, thiolate, dithiolate, quaternary ammonium, quaternary phosphonium, carbonium, ethynium, acetylene, ethenium, ethanium, or any combination thereof.

In at least one example embodiment, preparing the multivalent neutral organic salt includes reacting the modified photoactive ion with a counterion.

In at least one example embodiment, the method further includes increasing an open circuit voltage of the device by replacing or exchanging the counterion.

In at least one example embodiment, the incorporating includes spin-coating, spray-coating, web-coating, die-coating, or vapor-depositing a solution including the multivalent neutral organic salt onto a substrate.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic illustration of a photovoltaic (PV) in accordance with at least one example embodiment.

FIGS. 2A-2B are thin film absorption profiles for organic salts in accordance with at least one example embodiment. FIG. 2A depicts 100—Transmission (%) of organic salt films spun from 10 mg/mL solutions onto ITO covered glass substrates. FIG. 2B depicts molecular extinction coefficients calculated with optical constants from variable angle spectroscopic ellipsometry measurements.

FIGS. 3A-3H relate to anionic heptamethines that are used as donor compounds in photovoltaics in at least one example embodiment. FIGS. 3A-3D illustrate anionic heptamethines used in this example, which vary in charge (−1 or −3) or conjugation. FIG. 3A IS NaCy1. FIG. 3B IS Na₃Cy1′. FIG. 3C IS NaCy2. FIG. 3D IS Na₃Cy2′. FIG. 3E is a graph illustrating absorption (A) for the four chromophores. FIG. 3F is a graph illustrating photoluminescence (PL) data for the four chromophores. FIG. 3G is a schematic showing solar cell architecture with variable organic salt thickness and fixed acceptor (C₆₀) thickness. FIG. 3H is a schematic of the current generation process in organic salt photovoltaics.

FIGS. 4A-4D are mass spectrometry signals for anionic heptamethines in accordance with at least one example embodiment. Ultra high-performance liquid chromatography Xevo G2-XS QT of mass spectrometry isotope peaks for each of the four anionic heptamethines featured in this example. The expected m/z for the primary peak is given on each plot along with the relative abundance (%) in parentheses. Salts are dissolved in methanol at a concentration of 1 μM. FIG. 4A illustrates mass spectrometry for NaCy1. FIG. 4B illustrates mass spectrometry for NaCy1′. FIG. 4C illustrates mass spectrometry for NaCy2. FIG. 4D illustrates mass spectrometry for NaCy2′.

FIGS. 5A-5D are graphs illustrating thickness dependent current-voltage (J-V) data in accordance with at least one example embodiment. FIG. 5A illustrates J-V for NaCy1. FIG. 5B illustrates J-V for NaCy1. FIG. 5C illustrates J-V for NaCy2. FIG. 5D illustrates J-V for NaCy2′. Singly charged chromophores (FIGS. 5A and 5C) demonstrate significant loss in J_{sc} as organic salt thickness increases while triply charged salts (FIGS. 5B and 5D) demonstrate little decline in J_{sc}.

FIGS. 6A-6D are graphs illustrating EQE data for photovoltaic devices as a function of organic salt thickness, divided into regions of C₆₀ and organic salt absorption in accordance with at least one example embodiment. FIG. 6A illustrates EQE for NaCy1. FIG. 6B illustrates EQE for NaCy1. FIG. 6C illustrates EQE for NaCy2. FIG. 6D illustrates EQE for NaCy2′. Singly charged salts (FIGS. 6A and 6C) show large drop-off in both regions as the donor thickness is increased while triply charged salts (FIGS. 6B and 6D) demonstrate only slight drops in the C₆₀ region but severe loss in the organic salt absorption regime.

FIG. 7 is a table showing PV device parameters in accordance with at least one example embodiment.

FIG. 8 is a table showing characteristic parameters for anionic heptamethine based organic salts in accordance with at least one example embodiment. Bandgap is estimated from thin film absorption cutoffs for each salt. Exciton diffusion lengths extracted from transfer matrix optical modeling and a regression fit of EQE data. Charge collection are lengths extracted from a fit of organic salt thickness dependent EQE data at 440 nm using a modified charge collection efficiency equation. Hole mobilities from Mott-Gurney fitted J-V data collected from hole only devices. Hole lifetimes are determined from transient photovoltage decay fits. Charge diffusion length (L_{diff}) is calculated.

FIGS. 9A-9D are graphs showing fitted EQE data for the thinnest organic salt layer devices based on transfer matrix optical modeling in accordance with at least one example embodiment. FIG. 9A illustrates EQE for NaCy1. FIG. 9B illustrates EQE for NaCy1. FIG. 9C illustrates EQE for NaCy2.

FIG. 9D illustrates EQE for NaCy2′.

FIGS. 10A-10D are graphs showing organic salt thickness dependent EQE data fitted with a fixed fullerene (C₆₀) diffusion length in accordance with at least one example embodiment. Calculated EQE (smooth lines) at 440 nm are used as the pre-factor to modify the charge collection equation for charge collection length fitting. The gray “x”s indicate a poor fit to a spectral region. FIG. 10A illustrates EQE for NaCy1. FIG. 10B illustrates EQE for NaCy1′. FIG. 10C illustrates EQE for NaCy2. FIG. 10D illustrates EQE for NaCy2′.

FIGS. 11A-11F relate to isolating hole collection losses in organic salt photovoltaics in accordance with at least one example embodiment. FIGS. 11A-11D are graphs showing EQE at 440 nm (peak C₆₀ response) as a function of organic salt thickness (data points). Data fitted with fixed acceptor diffusion length but no organic salt charge collection losses (dashed line). Data fitted with a fixed L_{ED,A} and a charge collection model (solid line). FIG. 11A illustrates EQE for NaCy1. FIG. 11B illustrates EQE for NaCy1′. FIG. 11C illustrates EQE for NaCy2. FIG. 11D illustrates EQE for NaCy2′. FIG. 11E is a graph illustrating normalized EQE at 440 nm as a function of organic salt thickness with the charge collection model. FIG. 11F is a graph illustrating normalized IQE at 440 nm as a function of organic salt thickness with the charge collection model.

FIGS. 12A-12D are graphs illustrating current density (J) as a function of the squared potential (V²) from hole only devices for each organic salt fitted with the Mott-Gurney equation for space charge limited current in accordance with at least one example embodiment. Curves are fit where J is linearly related to V². FIG. 12A illustrates current density for NaCy1. FIG. 12B illustrates current density for NaCy1′. FIG. 12C illustrates current density for NaCy2. FIG. 12D illustrates current density for NaCy2′.

FIGS. 13A-13D are graphs illustrating photovoltage decay (data) as a function of time for each organic salt device fitted with an exponential decay function (black line) to extract the hole carrier lifetime in accordance with at least one example embodiment. FIG. 13A illustrates photovoltage for NaCy1. FIG. 13B illustrates photovoltage for NaCy1′. FIG. 13C illustrates photovoltage for NaCy2. FIG. 13D illustrates photovoltage for NaCy2′.

Corresponding reference numerals indicate corresponding parts throughout the several views of the drawings.

### DETAILED DESCRIPTION

Example embodiments will now be described more fully with reference to the accompanying drawings.

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

A photoactive layer is a layer including (or consisting of or consisting essentially of) one or more photoactive materials. A photoactive material is a material that absorbs light to generate charge carriers (known as photocurrent).

The present disclosure provides organic salts (e.g., multivalent organic salts) for photovoltaic (PV) devices. The organic salts include photoactive ion or chromophore (e.g., a cyanine) that is either a cation or anion and a counterion. The present disclosure also provides PV devices including the organic salts.

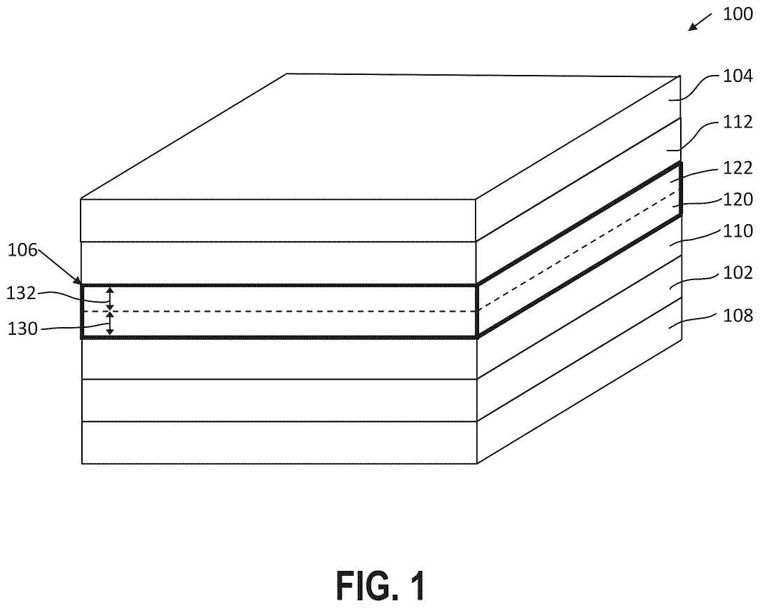

FIG. 1 illustrates a photovoltaic (PV) device 100 in accordance with at least one example embodiment. The PV device 100 generally includes a first electrode 102, a second electrode 104, and a photoactive layer 106 between the first and second electrodes 102, 104. In at least one example embodiment, one or both of the first and second electrodes 102, 104 may be on a substrate 108. In at least one example embodiment, the first electrode 102 may be positioned on the substrate 108 and include materials that act as the electrode, such that the substrate and electrode are visibly indistinguishable (not shown).

In at least one example embodiment, each of the electrodes 102, 104 may independently include thin metal (e.g., Ag, Au, Al, and/or Cu), indium tin oxide (ITO), tin oxide, aluminum doped zinc oxide, metallic nanotubes, metal nanowires (e.g., Ag, Au, Al, and/or Cu), conductive low-e stack, low-e single-silver stack, low-e double-silver stack, low-e triple-silver stack, or any combination thereof. In at least one example embodiments, one or both of the electrodes 102, 104 are transparent.

The substrate 108 may be transparent or opaque. In at least one example embodiment, the substrate 108 includes glass, plastic (e.g., polyethylene, polycarbonate, polymethyl methacrylate, and/or polydimethylsiloxane), or any combination thereof.

In at least one example embodiment, the PV device 100 further includes or more adjunct layers, such as a first adjunct layer 110 and a second adjunct layer 112. In the example embodiment shown, the first adjunct layer 110 is between the first electrode 102 and the photoactive layer 106. The second adjunct layer 112 is between the second electrode 104 and the photoactive layer 106. Each of the adjunct layers 110, 112 may include a hole transport layer, an electron blocking layer, a buffer layer, an electron transport layer, a hole blocking layer, an electron extraction layer, or any combination thereof. Although the example embodiment of FIG. 1 shows two adjunct layers 110, 112, a PV device in accordance with the present disclosure may be free of adjunct layers, include a single adjunct layer, or include more than two adjunct layers. In at least one example embodiment, the first adjunct layer is a hole transport layer and the second adjunct layer is an electron transport layer. In at least one other example embodiment, the first adjunct layer is an electron transport layer and the second adjunction layer is hole transport layer. In at least one other example embodiment, the first and second adjunct layers may be a conducting or semiconducting wetting layer. In at least one other example embodiment, the first and second adjunct layers may be hole or electron blocking layers. In at least one example embodiment, the adjunct layers may have compositions as described in PCT Patent Application No. PCT/US2019/030209, filed on May 1, 2019, and published as WO2019213265A1, which is incorporated herein by referenced in its entirety.

In at least one example embodiment, the electroactive layer 106 includes a donor material and an acceptor material. In at least the example embodiment shown, the electroactive layer 106 includes a first or donor layer 120 including the donor material and a second or acceptor layer 122 including the acceptor material. The donor and acceptor layers 120, 122 may be completely distinct, or include an intermediate region therebetween that includes both donor and acceptor materials (e.g., admixed and/or blended). In at least one other example embodiment, a photoactive layer may include admixed and/or blended donor and acceptor materials to form a bulk heterojunction (not shown).

In at least one example embodiment, the donor layer 120 defines a first thickness 130 of greater than or equal to about 5 nm (e.g., greater than or equal to about 10 nm, greater than or equal to about 15 nm, greater than or equal to about 20 nm, greater than or equal to about 25 nm, greater than or equal to about 30 nm, greater than or equal to about 40 nm, greater than or equal to about 50 nm, greater than or equal to about 75 nm, greater than or equal to about 100 nm, greater than or equal to about 125 nm, greater than or equal to about 150 nm, or greater than or equal to about 175 nm). The first thickness 130 may be less than or equal to about 200 nm (e.g., less than or equal to about 175 nm, less than or equal to about 150 nm, less than or equal to about 125 nm, less than or equal to about 100 nm, less than or equal to about 75 nm, less than or equal to about 50 nm, less than or equal to about 40 nm, less than or equal to about 30 nm, less than or equal to about 25 nm, less than or equal to about 20 nm, less than or equal to about 15 nm, or less than or equal to about 10 nm).

In at least one example embodiment, the donor layer 120 is continuous. As used herein, “continuous” means extending across an entire electrode or other layer and not in an island/sea configuration). In at least one example embodiment, the donor layer 120 is a continuous mesh. In at least one example embodiment, the donor layer 120 is neat. As used herein, “neat” means effectively uniform in composition (as opposed to doped or mixed) and/or that the material is deposited only of itself. In at least one example embodiment, the donor layer 120 consists essentially of a photoactive donor material. In at least one example embodiment, the first thickness 130 is substantially constant or uniform. In at least one example embodiment, the donor layer 120 is substantially uniform in composition. In at least one example embodiment, the donor layer 120 is smooth. As used herein, “smooth” means having a roughness of less than about one tenth.

In at least one example embodiment, the acceptor layer 122 defines a second thickness 132 of greater than or equal to about 5 nm (e.g., greater than or equal to about 10 nm, greater than or equal to about 15 nm, greater than or equal to about 20 nm, greater than or equal to about 25 nm, greater than or equal to about 30 nm, greater than or equal to about 40 nm, greater than or equal to about 50 nm, greater than or equal to about 75 nm, greater than or equal to about 100 nm, greater than or equal to about 125 nm, greater than or equal to about 150 nm, or greater than or equal to about 175 nm). The second thickness 132 may be less than or equal to about 200 nm (e.g., less than or equal to about 175 nm, less than or equal to about 150 nm, less than or equal to about 125 nm, less than or equal to about 100 nm, less than or equal to about 75 nm, less than or equal to about 50 nm, less than or equal to about 40 nm, less than or equal to about 30 nm, less than or equal to about 25 nm, less than or equal to about 20 nm, less than or equal to about 15 nm, or less than or equal to about 10 nm).

In at least one example embodiment, the acceptor layer 122 is continuous. In at least one example embodiment, the acceptor layer 122 is a continuous mesh. In at least one example embodiment, the acceptor layer 122 is neat. In at least one example embodiment, the acceptor layer 122 consists essentially of a photoactive donor material. In at least one example embodiment, the second thickness 132 is substantially constant or uniform. In at least one example embodiment, the acceptor layer 122 is substantially uniform in composition. In at least one example embodiment, the acceptor layer 122 is smooth.

The photoactive layer 106 includes at least one organic salt (i.e., as a donor material and/or an acceptor material). In at least one example embodiment, the organic salt is a multivalent organic salt. The multivalent organic salt includes photoactive ion or chromophore (e.g., cyanine) having a valence selected from the group consisting of: 1+, 2+, 3+, 4+, 5+, 6+, 7+, 8+1−, 2−, 3−, 4−, 5−, 6−, 7−, or 8− and a counterion having a valence selected from the group consisting of: 1+, 2+, 3+, 4+, 5+, 6+, 7+, 8+, 1−, 2−, 3−, 4−, 5−, 6−, 7−, or 8−. A sum of the magnitude (also referred to as the absolute value or modulus) of the photoactive ion valence and the magnitude of the counterion valence is greater than or equal to 3 (e.g., greater than or equal to 4, greater than or equal to 5, or greater than or equal to 6). In at least one example embodiment, the multivalent organic salt has the formula C_{y}^{x+}Aₓ^{y-}, where C is a cation, A is an anion, x=1+, 2+, 3+, 4+, 5+, 6+, 7+, or 8+, y=1−, 2−, 3−, 4−, 5−, or 6−, 7−, 8−, and the magnitude of x plus the magnitude of y is greater than or equal to 3 (so that |x|+|y|≥3). In at least one example embodiment, the magnitude of the valence of the photoactive ion is greater than the magnitude of the valence of the counterion. In at least one example embodiment, the multivalent organic salt is a neutral multivalent organic salt.

The photoactive ion may include a photoactive cation or a photoactive anion. In at least one example embodiment, the multivalent organic salt may include a photoactive cation and a counterion anion. In at least one other example embodiment, the multivalent salt includes a photoactive anion and a counterion cation. The counterion (i.e., the counterion anion or the counterion anion) may be non-photoactive or photoactive.

In at least one example embodiment, the photoactive ion is a cation. In at least one example embodiment, the multivalent organic salt includes a photoactive cation and a counterion anion. In at least one example embodiment, the photoactive cation includes 1-Butyl-2-(2-[3-[2-(1-butyl-1H-benzo[cd]indol-2-ylidene)-ethylidene]-2-phenyl-cyclopent-1-enyl]-vinyl)-benzo[cd]indolium, 1-Butyl-2-(2-[3-[2-(1-butyl-1H-benzo[cd]indol-2-ylidene)-ethylidene]-2-chloro-cyclohex-1-enyl]-vinyl)-benzo[cd]indolium, 1-Butyl-2-(2-[3-[2-(1-butyl-1H-benzo[cd]indol-2-ylidene)-ethylidene]-2-phenyl-cyclohex-1-enyl]-vinyl)-benzo[cd]indolium, 1-Butyl-2-(2-[3-[2-(1-butyl-1H-benzo[cd]indol-2-ylidene)-ethylidene]-2-diphenylamino-cyclopent-1-enyl]-vinyl)-benzo[cd]indolium, 1-Butyl-2-[7-(1-butyl-1H-benzo[cd]indol-2-ylidene)-hepta-1,3,5-trienyl]-benzo[cd]indolium, 2-[2-[2-chloro-3-[2-(1,3-dihydro-3,3-dimethyl-1-ethyl-2H-benz[e]indol-2-ylidene)ethylidene]-1-cyclohexen-1-yl]-ethenyl]-3,3-dimethyl-1-ethyl-1H-benz[e]indolium (“Cy”), N,N,N′,N′-Tetrakis-(p-di-n-butylaminophenyl)-p-benzochinon-bis-immonium, 4-[2-[2-Chloro-3-[(2,6-diphenyl-4H-thiopyran-4-ylidene)ethylidene]-1-cyclohexen-1-yl]ethenyl]-2,6-diphenylthiopyrylium, 1-Butyl-2-[2-[3-[(1-butyl-6-chlorobenz[cd]indol-2 (1H)-ylidene)ethylidene]-2-chloro-5-methyl-1-cyclohexen-1-yl]ethenyl]-6-chlorobenz[cd]indolium, 1-Butyl-2-[2-[3-[(1-butyl-6-chlorobenz[cd]indol-2 (1H)-ylidene)ethylidene]-2-chloro-1-cyclohexen-1-yl]ethenyl]-6-chlorobenz[cd]indolium, Dimethyl {4-[1,7,7-tris(4-dimethylaminophenyl)-2,4,6-heptatrienylidene]-2,5-cyclohexadien-1-ylidene}ammonium, 5,5′-Dichloro-11-diphenylamino-3,3′-diethyl-10,12-ethylenethiatricarbocyanine, 2-[2-[2-Chloro-3-[2-(1,3-dihydro-1,1,3-trimethyl-2H-benzo[e]-indol-2-ylidene)-ethylidene]-1-cyclohexen-1-yl]-ethenyl]-1,1,3-trimethyl-1H-benzo[e]indolium, 2-[2-[2-Chloro-3-[2-(1,3-dihydro-1,3,3-trimethyl-2H-indol-2-ylidene)-ethylidene]-1-cyclopenten-1-yl]-ethenyl]-1,3,3-trimethyl-3H-indolium, 2-[2-[3-[(1,3-Dihydro-3,3-dimethyl-1-propyl-2H-indol-2-ylidene)ethylidene]-2-(phenylthio)-1-cyclohexen-1-yl]ethenyl]-3,3-dimethyl-1-propylindolium, 1,1′,3,3,3′,3′-4,4′,5,5′-di-benzo-2,2′-indotricarbocyanine perchlorate, 2-[2-[2-Chloro-3-[2-(1,3-dihydro-1,3,3-trimethyl-2H-indol-2-ylidene)-ethylidene]-1-cyclohexen-1-yl]-ethenyl]-1,3,3-trimethyl-3H-indolium, 3,3′-Diethylthiatricarbocyanine, 2-[[2-[2-[4-(dimethylamino)phenyl]ethenyl]-6-methyl-4H-pyran-4-ylidene]methyl]-3-ethyl, 2-[7-(1,3-Dihydro-1,3,3-trimethyl-2H-indol-2-ylidene)-1,3,5-heptatrienyl]-1,3,3-trimethyl-3H-indolium, cyanine3 (Cy3), cyanine3.5 (Cy3.5), cyanine5 (Cy5), cyanine5.5 (Cy5.5), cyanine7 (Cy7), cyanine7.5 (Cy7.5), any derivative thereof, or any combination thereof.

The counterion anion may include a tetrel, a chalcogen, a halogen, a transition metal, an organic anion, or any combination thereof. In at least one example embodiment, the counterion anions may F—, Cl—, I—, and Br—; aryl borates, such as tetrakis(4-fluorophenyl) borate (FPhB—), cobalticarborane (CoCB—), tetrakis(pentafluorophenyl) borate (TPFB—), tetrakis[3,5-bis(trifluoro methyl)phenyl]borate (TFM—), Δ-tris(tetrachloro-1,2-benzene diolato)phosphate (V) (TRIS—), tetraphenylborate, tetra(p-tolyl) borate, tetrakis(4-biphenylyl) borate, tetrakis(1-imidazolyl) borate, tetrakis(2-thienyl) borate, tetrakis(4-chlorophenyl) borate, tetrakis(4-fluorophenyl) borate, tetrakis(4-tert-butylphenyl) borate, tetrakis[3,5-bis(trifluoromethyl)]borate, [4-[bis(2,4,6-trimethylphenyl)phosphino]-2,3,5,6-tetrafluorophenyl]hydrobis(2,3,4,5,6-pentafluorophenyl) borate, [4-di-tert-butylphosphino-2,3,5,6-tetrafluorophenyl]hydrobis(2,3,4,5,6-pentafluorophenyl) borate anion; (Λ,R)-(1,1′-binaphthalene-2,2′diolato) (bis(tetrachlor-1,2-benzenediolato)phosphate (V)) anion (BINPHAT-), hexafluoroantimonate (SbF6-), tetrafluoroborate (BF4-), acetate, trifluoracetate, benzene sulfonate, bis(trifluoromethane) sulfonimide (TFSI), alkylsulfate, tosylate, methanesulfonate, tetrakis(4-methylphenyl)-borane, tetra-4-biphenylylborate, tetrakis(4-methoxyphenyl) borate, tetrakis[4-(2-methyl-2-propanyl)phenyl]borate, (2-methylphenyl) (triphenyl) borate, bis(2-methylphenyl) (diphenyl) borate, tetrakis(4′-methyl-4-biphenylyl) borate, tetrakis(4-isopropoxyphenyl) borate, perchlorate, hypochlorite, chlorite, chlorate, OH—, [SO4]²⁻, any derivative thereof, or any combination thereof

In at least one other example embodiment, the photoactive ion is an anion. In at least one example embodiment, the photoactive ion is a photoactive anion and the counterion is a cation. The photoactive anion may include 2-[2-[2-Chloro-3-[[1,3-dihydro-1,1-dimethyl-3-(4-sulfobutyl)-2H-benzo[e]indol-2-ylidene]-ethylidene]-1-cyclohexen-1-yl]-ethenyl]-1,1-dimethyl-3-(4-sulfobutyl)-1H-benzo[e]indolium hydroxide, 2-[2-[2-Chloro-3-[[1,3-dihydro-1,1-dimethyl-3-(4-sulfobutyl)-2H-benzo[e]indol-2-ylidene]-ethylidene]-1-cyclohexen-1-yl]-ethenyl]-1,1-dimethyl-3-(4-sulfobutyl)-1H-benzo[e]indolium hydroxide, 5-Chloro-2-[2-(3-[2-[5-chloro-3-(4-sulfobutyl)-3H-benzothiazol-2-ylidene]-ethylidene]-2-diphenylaminocyclopent-1-enyl)-vinyl]-3-(4-sulfobutyl)-benzothiazolium hydroxide, 2-[2-[2-Chloro-3-[2-[1,3-dihydro-3,3-dimethyl-1-(4-sulfobutyl)-2H-indol-2-ylidene]-ethylidene]-1-cyclopenten-1-yl]-ethenyl]-3,3-dimethyl-1-(4-sulfobutyl)-3H-indolium hydroxide, 5-Chloro-2-[2-(3-[2-[5-chloro-3,3-dimethyl-1-(4-sulfobutyl)-1,3-dihydro-indol-2-ylidene]-ethylidene]-2-diphenylamino-cyclopent-1-enyl)-vinyl]-3,3-dimethyl-1-(4-sulfobutyl)-3H-indolium hydroxide, 5-Chloro-2-[2-(3-[2-[5-chloro-3-(4-sulfobutyl)-3H-benzothiazol-2-ylidene]-ethylidene]-2-phenylcyclohex-1-enyl)-vinyl]-3-(4-sulfobutyl)-benzothiazol-3-ium hydroxide, 3,3-Dimethyl-2-[2-[2-chloro-3-[2-[1,3-dihydro-3,3-dimethyl-5-sulfo-1-(4-sulfobutyl)-2H-indol-2-ylidene]-ethylidene]-1-cyclohexen-1-yl]-ethenyl]-5-sulfo-1-(4-sulfobutyl)-3H-indolium hydroxide 2-[2-[2-Chloro-3-[2-[1,3-dihydro-3,3-dimethyl-1-(4-sulfobutyl)-2H-indol-2-ylidene]-ethylidene]-1-cyclohexen-1-yl]-ethenyl]-3,3-dimethyl-1-(4-sulfobutyl)-3H-indolium hydroxide 2-[2-(3-[2-[3,3-Dimethyl-5-sulfo-1-(4-sulfobutyl)-1,3-dihydro-indol-2-ylidene]-ethylidene]-2-phenylcyclohex-1-enyl)-vinyl]-3,3-dimethyl-5-sulfo-1-(4-sulfobutyl)-3H-indolium hydroxide, 2-[7-[1,3-Dihydro-3,3-dimethyl-1-(4-sulfobutyl)-2H-indol-2-ylidene]-hepta-1,3,5-trienyl]-3,3-dimethyl-1-(4-sulfobutyl)-3H-indolium hydroxide, 2-[5-[1,1-Dimethyl-3-(4-sulfobutyl)-1,3-dihydro-benzo[e]indol-2-ylidene]-penta-1,3-dienyl]-1,1-dimethyl3-(4-sulfobutyl)-1H-benzo[e]indolium hydroxide, 5-Chloro-2-[5-[5-chloro-3-(4-sulfobutyl)-3H-benzothiazol-2-ylidene]-penta-1,3-dienyl]-3-(4-sulfobutyl)-benzothiazol-3-ium hydroxide, inner salt, 5-Chloro-2-[5-[5-chloro-3-(4-sulfobutyl)-3H-benzothiazol-2-ylidene]-3-phenyl-penta-1,3-dienyl]-3-(4-sulfobutyl)-benzothiazol-3-ium hydroxide, 2-[5-[3,3-Dimethyl-1-(4-sulfobutyl)-1,3-dihydro-indol-2-ylidene]-penta-1,3-dienyl]-3,3-dimethyl-1-(4-sulfobutyl)-3H-indolium hydroxide, 2-[3-[1,1-Dimethyl-3-(4-sulfobutyl)-1,3-dihydro-benzo[e]indol-2-ylidene]-propenyl]-1,1-dimethyl-3-(4-sulfobutyl)-1H-benzo[e]indolium hydroxide, 5,6-Dichloro-2-[[5,6-dichloro-1-ethyl-3-(4-sulfobutyl)-benzimidazol-2-ylidene]-propenyl]-1-ethyl-3-(4-sulfobutyl)-benzimidazolium hydroxide, 3-(4-Sulfobutyl)-2-[3-[3-(4-sulfobutyl)-3H-benzooxazol-2-ylidene]-propenyl]-benzoxazolium hydroxide 2-[2-(2-Chloro-3-[2-[1,1-dimethyl-7-sulfo-3-(4-sulfobutyl)-1,3-dihydro-benzo[e]indol-2-ylidene]-ethylidene]-cyclohex-1-enyl)-vinyl]-1,1-dimethyl-7-sulfo-3-(4-sulfobutyl)-1H-benzo[e]indolium hydroxide, 2-[2-(2-Chloro-3-[2-[1,1-dimethyl-7-sulfo-3-(4-sulfobutyl)-1,3-dihydro-benzo[e]indol-2-ylidene]-ethylidene]-cyclopent-1-enyl)-vinyl]-1,1-dimethyl-7-sulfo-3-(4-sulfobutyl)-1H-benzo[e]indolium hydroxide, or ((Z)-4-((E)-2-(2-chloro-3-((E)-2-(4-cyano-5-(dicyanomethylene)-2-methyl-2-(trifluoromethyl)-2,5-dihydrofuran-3-yl) vinyl)cyclohex-2-en-1-ylidene)ethylidene)-3-cyano-5-methyl-5-(trifluoromethyl)-4,5-dihydrofuran-2-yl)dicyanomethanide, ((Z)-4-((E)-2-(2-chloro-3-((E)-2-(4-cyano-5-(dicyanomethylene)-2-methyl-2-(methyl)-2,5-dihydrofuran-3-yl) vinyl)cyclohex-2-en-1-ylidene)ethylidene)-3-cyano-5-methyl-5-(methyl)-4,5-dihydrofuran-2-yl)dicyanomethanide, ((Z)-4-((E)-2-(2-chloro-3-((E)-2-(4-cyano-5-(dicyanomethylene)-2,5-dihydrofuran-3-yl) vinyl)cyclohex-2-en-1-ylidene)ethylidene)-3-cyano-4,5-dihydrofuran-2-yl)dicyanomethanide, ((Z)-4-((E)-2-(3-((E)-2-(4-cyano-5-(dicyanomethylene)-2,5-dihydrofuran-3-yl) vinyl)cyclohex-2-en-1-ylidene)ethylidene)-3-cyano-4,5-dihydrofuran-2-yl)dicyanomethanide, sulfonated cyanine3 (Cy3), sulfonated cyanine3.5 (Cy3.5), sulfonated cyanine5 (Cy5), sulfonated cyanine5.5 (Cy5.5), sulfonated cyanine7 (Cy7), sulfonated cyanine7.5 (Cy7.5), derivatives thereof, halogenated derivatives thereof, or any combination thereof.

In at least one example embodiment, the counterion cation may include an alkali metal, an alkaline earth metal, a transition metal, a triel, a tetral, a pnictogen, an organic cation, or any combination thereof. In at least one example embodiment, the counterion cation may include Li+, Na+, K+, Rb+, Cs+, Be2+, Mg2+, Ca2+, Sr2+, Ba2+, Al2+, Sc2+, Sc3+, Ti4+, Fe2+, Fe3+, Sn2+, Sn4+, Zn2+, [NH4]+, [N (C₄H₉)₄]⁺, (2-oxo-2-phenyl-ethyl)-triphenyl-phosphonium, 1-benzyl-4-(4-methoxy-phenyl)-4H-(1,2,4)triazol-1-ium, 1-benzyl-4-phenyl-3-styryl-4H-(1,2,4)triazol-1-ium, 1-benzyl-4-phenyl-3-styryl-4H-(1,2,4)triazol-1-ium, 2,4,6 tris-(4-chloro-phenyl)-pyranylium, 2,4,6-tris-(4-chloro-phenyl)-thiopyranylium, 2,4,6-tris-(4-hydroxy-phenyl)-pyranylium, 2,4,6-tris-(4-tert-butyl-phenyl)-(1,3) oxazin-1-ylium, 4,6-bis-(4-chloro-phenyl)-2,3-diphenyl-pyranylium, 1-hexyl-3-methylimidazolium, 1-hexyl-3-(3,3,4,4,5,5,6,6-tridecafluorooctyl)-methylimidazolium, 1-hexyl-3-(3,3,4,4,5,5,6,6,7,7,8,8-nonafluorohexyl)-methylimidazolium, methylpyridinium, trimethylmethanaminium, methyl ammonium, acetamidinium, 5-azaspiro[4.4]nonan-5-ium, benzylammonium, iso-butylammonium, n-butylammonium, t-butylammonium, cyclohexylammonium, 1,4-diazabicyclo[2,2,2]octane-1,4-diium, diethylammonium, ethane-1,2-diammonium, ethylammonium, formamidinium, guanidinium, n-hexylammonium, imidazolium, n-octylammonium, phenethylammonium, piperazine-1,4-diium, propane-1,3-diammonium, iso-propylammonium, pyrrolidinium, quinuclidin-1-ium, phosphonium, pyrrolidium, thiazolium, sulfinium, imidazolium, pyridinium methylammonium (MA), formamidinium (FA), ethanediaminium (EA), iso-propylammonium, dimethylammonium, guanidinium, piperidinium, pyridinium, pyrrolidinium, imidazolium, t-butylammonium (2-oxo-2-phenyl-ethyl)-triphenyl-phosphonium, 1-benzyl-4-(4-methoxy-phenyl)-4H-(1,2,4)triazol-1-ium, 1-benzyl-4-phenyl-3-styryl-4H-(1,2,4)triazol-1-ium, 1-benzyl-4-phenyl-3-styryl-4H-(1,2,4)triazol-1-ium, 2,4,6 tris-(4-chloro-phenyl)-pyranylium, 2,4,6-tris-(4-chloro-phenyl)-thiopyranylium, 2,4,6-tris-(4-hydroxy-phenyl)-pyranylium, 2,4,6-tris-(4-tert-butyl-phenyl)-(1,3) oxazin-1-ylium, 4,6-bis-(4-chloro-phenyl)-2,3-diphenyl-pyranylium, 1-hexyl-3-methylimidazolium, 1-hexyl-3-(3,3,4,4,5,5,6,6-tridecafluorooctyl)-methylimidazolium, 1-hexyl-3-(3,3,4,4,5,5,6,6,7,7,8,8-nonafluorohexyl)-methylimidazolium, methylpyridinium, trimethylmethanaminium, methyl ammonium, acetamidinium, 5-azaspiro[4.4]nonan-5-ium, benzylammonium, iso-butylammonium, n-butylammonium, t-butylammonium, cyclohexylammonium, 1,4-diazabicyclo[2,2,2]octane-1,4-diium, diethylammonium, ethane-1,2-diammonium, ethylammonium, formamidinium, guanidinium, n-hexylammonium, imidazolium, n-octylammonium, phenethylammonium, piperazine-1,4-diium, propane-1,3-diammonium, iso-propylammonium, pyrrolidinium, quinuclidin-1-ium, phosphonium, pyrrolidium, thiazolium, sulfinium, imidazolium, pyridinium, sulfonated cyanine3 (Cy3), sulfonated cyanine3.5 (Cy3.5), sulfonated cyanine5 (Cy5), sulfonated cyanine5.5 (Cy5.5), sulfonated cyanine7 (Cy7), sulfonated cyanine7.5 (Cy7.5) or any combination thereof, or any combination thereof.

In at least one example embodiment, the photoactive ion is a cationic or anionic form of a photoactive molecule including porphyrin(s), rhodamine(s), cyanine(s), polymethine(s), heptamethine(s), phthalocyanine(s), squaraine(s), perylene(s), quinine(s), xanthene(s), naphthalene(s), coumarin(s), oxadiazole(s), oxazine(s), acridine(s), arylmethine(s), tetrapyrrole(s), indocarbocyanine(s), oxacarbocyanine(s), thiacarbocyanine(s), merocyanine(s), porfimer(s), any derivative thereof, or any combinations thereof.

In one aspect, the photoactive ion is a photoactive cation including 1-Butyl-2-(2-[3-[2-(1-butyl-1H-benzo[cd]indol-2-ylidene)-ethylidene]-2-phenyl-cyclopent-1-enyl]-vinyl)-benzo[cd]indolium, 1-Butyl-2-(2-[3-[2-(1-butyl-1H-benzo[cd]indol-2-ylidene)-ethylidene]-2-chloro-cyclohex-1-enyl]-vinyl)-benzo[cd]indolium, 1-Butyl-2-(2-[3-[2-(1-butyl-1H-benzo[cd]indol-2-ylidene)-ethylidene]-2-phenyl-cyclohex-1-enyl]-vinyl)-benzo[cd]indolium, 1-Butyl-2-(2-[3-[2-(1-butyl-1H-benzo[cd]indol-2-ylidene)-ethylidene]-2-diphenylamino-cyclopent-1-enyl]-vinyl)-benzo[cd]indolium, 1-Butyl-2-[7-(1-butyl-1H-benzo[cd]indol-2-ylidene)-hepta-1,3,5-trienyl]-benzo[cd]indolium, 2-[2-[2-chloro-3-[2-(1,3-dihydro-3,3-dimethyl-1-ethyl-2H-benz[e]indol-2-ylidene)ethylidene]-1-cyclohexen-1-yl]-ethenyl]-3,3-dimethyl-1-ethyl-1H-benz[e]indolium (“Cy”), N,N,N′,N′-Tetrakis-(p-di-n-butylaminophenyl)-p-benzochinon-bis-immonium, 4-[2-[2-Chloro-3-[(2,6-diphenyl-4H-thiopyran-4-ylidene)ethylidene]-1-cyclohexen-1-yl]ethenyl]-2,6-diphenylthiopyrylium, 1-Butyl-2-[2-[3-[(1-butyl-6-chlorobenz[cd]indol-2 (1H)-ylidene)ethylidene]-2-chloro-5-methyl-1-cyclohexen-1-yl]ethenyl]-6-chlorobenz[cd]indolium, 1-Butyl-2-[2-[3-[(1-butyl-6-chlorobenz[cd]indol-2 (1H)-ylidene)ethylidene]-2-chloro-1-cyclohexen-1-yl]ethenyl]-6-chlorobenz[cd]indolium, Dimethyl {4-[1,7,7-tris(4-dimethylaminophenyl)-2,4,6-heptatrienylidene]-2,5-cyclohexadien-1-ylidene}ammonium, 5,5′-Dichloro-11-diphenylamino-3,3′-diethyl-10,12-ethylenethiatricarbocyanine, 2-[2-[2-Chloro-3-[2-(1,3-dihydro-1,1,3-trimethyl-2H-benzo[e]-indol-2-ylidene)-ethylidene]-1-cyclohexen-1-yl]-ethenyl]-1,1,3-trimethyl-1H-benzo[e]indolium, 2-[2-[2-Chloro-3-[2-(1,3-dihydro-1,3,3-trimethyl-2H-indol-2-ylidene)-ethylidene]-1-cyclopenten-1-yl]-ethenyl]-1,3,3-trimethyl-3H-indolium, 2-[2-[3-[(1,3-Dihydro-3,3-dimethyl-1-propyl-2H-indol-2-ylidene)ethylidene]-2-(phenylthio)-1-cyclohexen-1-yl]ethenyl]-3,3-dimethyl-1-propylindolium, 1,1′,3,3,3′,3′-4,4′,5,5′-di-benzo-2,2′-indotricarbocyanine perchlorate, 2-[2-[2-Chloro-3-[2-(1,3-dihydro-1,3,3-trimethyl-2H-indol-2-ylidene)-ethylidene]-1-cyclohexen-1-yl]-ethenyl]-1,3,3-trimethyl-3H-indolium, 3,3′-Diethylthiatricarbocyanine, 2-[[2-[2-[4-(dimethylamino)phenyl]ethenyl]-6-methyl-4H-pyran-4-ylidene]methyl]-3-ethyl, 2-[7-(1,3-Dihydro-1,3,3-trimethyl-2H-indol-2-ylidene)-1,3,5-heptatrienyl]-1,3,3-trimethyl-3H-indolium, cyanine3 (Cy3), cyanine3.5 (Cy3.5), cyanine5 (Cy5), cyanine5.5 (Cy5.5), cyanine7 (Cy7), cyanine7.5 (Cy7.5), any derivative thereof, or any combination thereof.

In at least one example embodiment, the donor layer 120 includes a first multivalent salt. The donor layer 120 may optionally include one or more additional organic salts, such as another multivalent salt or a single valent organic salt, which may be admixed or blended with the first multivalent salt. Additionally or alternatively, the donor layer 120 may include a photoactive donor material that is not an organic salt, such as phthalocyanine, cyanine, coumarin, porphyrin, naphthalocyanine, squaraine, perylene, thiophene, acene, BODIPY, rhodamine(s), quinine(s), xanthene(s), naphthalene(s), oxadiazole(s), oxazine(s), acridine(s), arylmethine(s), tetrapyrrole(s), indocarbocyanine(s), oxacarbocyanine(s), thiacarbocyanine(s), merocyanine(s), any derivative thereof, or any combination thereof. At least one example embodiment includes quaternizing one or more amine positions to form one or more salt (positive-negative) pairs. At least one other example embodiment includes adding (decorating) sulfonate groups around the molecule.

In at least one example embodiment, the acceptor layer 122 includes a second multivalent salt. The acceptor layer 122 may optionally include one or more additional organic salts, such as another multivalent salt or a single valent organic salt, which may be admixed or blended with the second multivalent salt. Additionally or alternatively, the acceptor layer 122 may include a photoactive acceptor material that is not an organic salt, such as a fullerene, TiO₂, ZnO, NiO, carbon nanotubes, non-fullerene acceptor, or any combination thereof.

In at least one example embodiment, a layer including the multivalent salt (e.g., the donor layer 120, the acceptor layer 122, and/or the photoactive layer 106 in the case of a bulk heterojunction) is substantially homogeneous. In at least one other example embodiment, a layer including the multivalent salt (e.g., the donor layer 120, the acceptor layer 122, and/or the photoactive layer 106 in the case of a bulk heterojunction) is crystalline and/or nanocrystalline.

In at least one example embodiment, the donor layer 120 a peak absorption at a wavelength of greater than or equal to about 650 nm (e.g., greater than or equal to about 660 nm, greater than or equal to about 670 nm, greater than or equal to about 680 nm, greater than or equal to about 690 nm, greater than or equal to about 700 nm, greater than or equal to about 720 nm, greater than or equal to about 740 nm, greater than or equal to about 760 nm, greater than or equal to about 780 nm, greater than or equal to about 800 nm, greater than or equal to about 820 nm, greater than or equal to about 840 nm, greater than or equal to about 860 nm, greater than or equal to about 880 nm, or greater than or equal to about 900 nm). In at least one example embodiment, the donor peak absorption is at a wavelength of less than or equal to about 1,200 nm (e.g., less than or equal to about 1,150 nm, less than or equal to about 1,100 nm, less than or equal to about 1,050 nm, less than or equal to about 1,000 nm, or less than or equal to about 950 nm). In at least one example embodiment, the donor layer 120 has a peak absorption at a wavelength of less than or equal to about 450 nm (e.g., less than or equal to about 440 nm, less than or equal to about 430 nm, less than or equal to about 420 nm, less than or equal to about 410 nm, or less than or equal to about 400 nm). In at least one example embodiment, the donor layer 120 has greater than or equal to one absorption peak (e.g., greater than or equal to two absorption peaks, greater than or equal to three absorption peaks, greater than or equal to four absorption peaks, greater than or equal to five absorption peaks) in the above wavelength ranges. The donor layer 120 may have less than or equal to about six absorption peaks (e.g., less than or equal to about five, less than or equal to about four, less than or equal to about three, or less than or equal to about two) in the above wavelength ranges. In at least one example embodiment, the donor layer 120 has no highest absorption peak (e.g., no first and second highest absorption peaks; no first, second, or third highest absorption peaks) in a range of greater than or equal to about 450 nm to less than or equal to about 650 nm (e.g., greater than or equal to about 440 nm to less than or equal to about 660 nm, greater than or equal to about 430 nm to less than or equal to about 670 nm, greater than or equal to about 420 nm to less than or equal to about 680 nm, greater than or equal to about 410 nm to less than or equal to about 690 nm, greater than or equal to about 400 nm to less than or equal to about 700 nm).

In at least one example embodiment, the acceptor layer 122 a peak absorption at a wavelength of greater than or equal to about 650 nm (e.g., greater than or equal to about 660 nm, greater than or equal to about 670 nm, greater than or equal to about 680 nm, greater than or equal to about 690 nm, greater than or equal to about 700 nm, greater than or equal to about 720 nm, greater than or equal to about 740 nm, greater than or equal to about 760 nm, greater than or equal to about 780 nm, greater than or equal to about 800 nm, greater than or equal to about 820 nm, greater than or equal to about 840 nm, greater than or equal to about 860 nm, greater than or equal to about 880 nm, or greater than or equal to about 900 nm). In at least one example embodiment, the acceptor peak absorption is at a wavelength of less than or equal to about 1,200 nm (e.g., less than or equal to about 1,150 nm, less than or equal to about 1,100 nm, less than or equal to about 1,050 nm, less than or equal to about 1,000 nm, or less than or equal to about 950 nm). In at least one example embodiment, the acceptor layer 122 has a peak absorption at a wavelength of less than or equal to about 450 nm (e.g., less than or equal to about 440 nm, less than or equal to about 430 nm, less than or equal to about 420 nm, less than or equal to about 410 nm, or less than or equal to about 100 nm). In at least one example embodiment, the acceptor layer 122 has greater than or equal to one absorption peak (e.g., greater than or equal to two absorption peaks, greater than or equal to three absorption peaks, greater than or equal to four absorption peaks, greater than or equal to five absorption peaks) in the above wavelength ranges. The acceptor layer 122 may have less than or equal to about six absorption peaks (e.g., less than or equal to about five, less than or equal to about four, less than or equal to about three, or less than or equal to about two) in the above wavelength ranges. In at least one example embodiment, the acceptor layer 122 has no highest absorption peak (e.g., no first and second highest absorption peaks; no first, second, or third highest absorption peaks) in a range of greater than or equal to about 450 nm to less than or equal to about 650 nm (e.g., greater than or equal to about 440 nm to less than or equal to about 660 nm, greater than or equal to about 430 nm to less than or equal to about 670 nm, greater than or equal to about 420 nm to less than or equal to about 680 nm, greater than or equal to about 410 nm to less than or equal to about 690 nm, greater than or equal to about 400 nm to less than or equal to about 700 nm).

In at least one example embodiment, the PV device 100 has a peak absorption at a wavelength of greater than or equal to about 650 nm (e.g., greater than or equal to about 660 nm, greater than or equal to about 670 nm, greater than or equal to about 680 nm, greater than or equal to about 690 nm, greater than or equal to about 700 nm, greater than or equal to about 720 nm, greater than or equal to about 740 nm, greater than or equal to about 760 nm, greater than or equal to about 780 nm, greater than or equal to about 800 nm, greater than or equal to about 820 nm, greater than or equal to about 840 nm, greater than or equal to about 860 nm, greater than or equal to about 880 nm, or greater than or equal to about 900 nm). In at least one example embodiment, the device peak absorption is at a wavelength of less than or equal to about 1,200 nm (e.g., less than or equal to about 1,150 nm, less than or equal to about 1,100 nm, less than or equal to about 1,050 nm, less than or equal to about 1,000 nm, or less than or equal to about 950 nm). In at least one example embodiment, the PV device 100 has a peak absorption at a wavelength of less than or equal to about 450 nm (e.g., less than or equal to about 440 nm, less than or equal to about 430 nm, less than or equal to about 420 nm, less than or equal to about 410 nm, or less than or equal to about 400 nm). In at least one example embodiment, the PV device 100 has greater than or equal to one absorption peak (e.g., greater than or equal to two absorption peaks, greater than or equal to three absorption peaks, greater than or equal to four absorption peaks, greater than or equal to five absorption peaks) in the above wavelength ranges. The PV device 100 may have less than or equal to about six absorption peaks (e.g., less than or equal to about five, less than or equal to about four, less than or equal to about three, or less than or equal to about two) in the above wavelength ranges. In at least one example embodiment, the entire PV device 100 has no highest absorption peak (e.g., no first and second highest absorption peaks; no first, second, or third highest absorption peaks) in a range of greater than or equal to about 450 nm to less than or equal to about 650 nm (e.g., greater than or equal to about 440 nm to less than or equal to about 660 nm, greater than or equal to about 430 nm to less than or equal to about 670 nm, greater than or equal to about 420 nm to less than or equal to about 680 nm, greater than or equal to about 410 nm to less than or equal to about 690 nm, greater than or equal to about 400 nm to less than or equal to about 700 nm).

In at least one example embodiment, the multivalent organic salt has a bandgap of less than or equal to about 2 eV (e.g., less than or equal to about 1.9 eV, less than or equal to about 1.8 eV, less than or equal to about 1.7 eV, less than or equal to about 1.6 eV, less than or equal to about 1.5 eV, less than or equal to about 1.4 eV, less than or equal to about 1.3 eV, less than or equal to about 1.2 eV, less than or equal to about 1.1 eV, less than or equal to about 1 eV, less than or equal to about 0.9 eV, or less than or equal to about 0.8 eV).

As used herein, “exciton diffusion length” means the average distance over which an exciton will diffuse before it is annihilated to form heat or light. It is similar to, or synonymous with, the root mean square displacement of the exciton over the natural lifetime of the exciton. In at least one example embodiment, the multivalent organic salt has a exciton diffusion length of greater than or equal to about 10 nm (e.g., greater than or equal to about 20 nm, greater than or equal to about 30 nm, greater than or equal to about 40 nm, greater than or equal to about 50 nm, greater than or equal to about 100 nm, greater than or equal to about 150 nm, greater than or equal to about 200 nm, or greater than or equal to about 250 nm). The exciton diffusion length may be less than or equal to about 300 nm (e.g., less than or equal to about 250 nm, less than or equal to about 200 nm, less than or equal to about 100 nm, less than or equal to about 50 nm, less than or equal to about 40 nm, less than or equal to about 30 nm, less than or equal to about 20 nm, or less than or equal to about 10 nm).

As used herein, “charge collection length” means the length over which the charge can be readily collected before it is trapped or annihilated. In at least one example embodiment, the multivalent organic salt has a charge collection length of greater than or equal to about 10 nm (e.g., greater than or equal to about 20 nm, greater than or equal to about 30 nm, greater than or equal to about 40 nm, greater than or equal to about 50 nm, greater than or equal to about 100 nm, greater than or equal to about 200 nm, greater than or equal to about 300 nm, greater than or equal to about 400 nm, greater than or equal to about 500 nm, greater than or equal to about 600 nm, greater than or equal to about 700 nm, greater than or equal to about 800 nm, greater than or equal to about 900 nm, greater than or equal to about 1,000 nm, greater than or equal to about 2,000 nm, greater than or equal to about 3,000 nm, or greater than or equal to about 5,000 nm). The charge collection length may be less than or equal to about 10,000 nm (e.g., less than or equal to about 5,000 nm, less than or equal to about 3,000 nm, less than or equal to about 2,000 nm, less than or equal to about 1,000 nm, less than or equal to about 900 nm, less than or equal to about 800 nm, less than or equal to about 700 nm, less than or equal to about 600 nm, less than or equal to about 500 nm, less than or equal to about 400 nm, less than or equal to about 300 nm, less than or equal to about 200 nm, less than or equal to about 100 nm, less than or equal to about 50 nm, less than or equal to about 40 nm, less than or equal to about 30 nm, or less than or equal to about 20 nm).

In at least one example embodiment, the multivalent organic salt has a highest occupied molecular orbital (HOMO) level of greater than or equal to about 3.5 eV (e.g., greater than or equal to about 3.75 eV, greater than or equal to about 4 eV, greater than or equal to about 4.25 eV, greater than or equal to about 4.5 eV, greater than or equal to about 4.75 eV, greater than or equal to about 5 eV, greater than or equal to about 5.25 eV, greater than or equal to about 5.5 eV, or greater than or equal to about 5.75 eV). The HOMO level may be less than or equal to about 6 eV (e.g., less than or equal to about 5.75 eV, less than or equal to about 5.5 eV, less than or equal to about 5.25 eV, less than or equal to about 5 eV, less than or equal to about 4.75 eV, less than or equal to about 4.5 eV, less than or equal to about 4.25 eV, less than or equal to about 4 eV, or less than or equal to about 3.75 eV).

In at least one example embodiment, the PV device 100 has an average visible transmittance (AVT) of greater than or equal to about 0% (e.g., greater than or equal to about 10%, greater than or equal to about 20%, greater than or equal to about 30%, greater than or equal to about 40%, greater than or equal to about 50%, greater than or equal to about 60%, greater than or equal to about 70%, greater than or equal to about 80%, or greater than or equal to about 90%). The AVT may be less than or equal to about 100% (e.g., less than or equal to about 90%, less than or equal to about 80%, less than or equal to about 70%, less than or equal to about 60%, less than or equal to about 50%, less than or equal to about 40%, less than or equal to about 30%, or less than or equal to about 20%). In at least one example embodiment, the PV device 100 is opaque.

As used herein, “external quantum efficiency” (EQE) is the efficiency of converting photons of a particular wavelength to electrons. In at least one example embodiment, the PV device 100 has a maximum external quantum efficiency (max EQE) of greater than or equal to about 0.1% (e.g., greater than or equal to about 1%, greater than or equal to about 2%, greater than or equal to about 5%, greater than or equal to about 8%, greater than or equal to about 10%, or greater than or equal to about 12%).

In at least one example embodiment, the PV device 100 has a power conversion efficiency (PCE) of greater than or equal to about 0.5% (e.g., greater than or equal to about 0.6%, greater than or equal to about 0.7%, greater than or equal to about 0.8%, greater than or equal to about 0.9%, or greater than or equal to about 1.0%).

In at least one example embodiment, the PV device has an open circuit voltage (Voc) greater than or equal to about 40% of the excitonic voltage limit (e.g., greater than or equal to about 45%, greater than or equal to about 50%, greater than or equal to about 55%, greater than or equal to about 60%, or greater than or equal to about 65%), as defined in Lunt et al., “Practical Roadmap and Limits to Nanostructured Photovoltaics” (Perspective) Adv. Mat. 23, 5712-5727, 2011, which is incorporated herein by reference.

In at least one example embodiment, the PV device 100 has a fill factor of greater than or equal to about 0.45 (e.g., greater than or equal to about 0.5, greater than or equal to about 0.55, or greater than or equal to about 0.6).

In at least one example embodiment, a method of preparing a photoactive layer including a multivalent organic for use in a PV device is provided. The method generally includes providing a photoactive ion (i.e., a cation or anion); preparing a modified photoactive ion by increasing an overall valence of the photoactive ion; preparing a multivalent neutral organic salt; and incorporating the multivalent neutral organic salt into a photoactive layer of a PV device. Increasing the overall valence of the photoactive ion may include reacting the photoactive ion and/or adding charged groups. In at least one example embodiment, charged groups may include sulfonate, dinitrile, thiolate, dithiolate, quaternary ammonium, quaternary phosphonium, carbonium, ethynium, acetylene, ethenium, ethanium, or any combination thereof. Preparing the multivalent neutral organic salt may include reacting the modified photoactive ion with a counterion. Incorporating the multivalent neutral organic salt into a PV device may include depositing a layer including the multivalent neutral organic salt onto a substrate, an electrode, or an adjunct layer. In at least one example embodiment, depositing is performed using spin-coating, vapor deposition, spray coating, slot-die coating, web coating, curtain coating (e.g., in addition to spin-coating, or any combination thereof. In at least one example embodiment, the method further includes replacing or exchanging the counterion to increase the open circuit voltage, as described in U.S. application Ser. No. 15/791,949 filed on Oct. 24, 2017 and issued as U.S. Pat. No. 11,114,623 on Sep. 7, 2021, which is incorporated by reference herein in its entirety.

### Example

### Methods.

Experimental: PV device fabrication began with pre-patterned ITO coated glass substrates cleaned via sequential sonication for 10 minutes in deionized water, acetone, and isopropanol. Substrates are dried on a hotplate at 100° C. for one minute before plasma cleaning for 10 minutes. Cleaned substrates are loaded into an Angstrom Engineering thermal vapor deposition chamber and 10 nm of MoO₃ was deposited at a base pressure of 3×10−6 torr. Organic salts are dissolved in methanol at concentrations of 1-10 mg/mL and neat films are spun on MoO₃ at 2000 rpm to yield films with thicknesses ranging from 3 to 70 nm as measured by variable angle spectroscopic ellipsometry (VASE) (Woollam Ellipsometer) on Si substrates. Substrates with organic salt and MoO₃ films are loaded into the deposition chamber where 40 nm of C₆₀, 7.5 nm BCP, and 80 nm Ag are deposited to complete the device stack. A special mask was used for Ag deposition to define an active area of 4.43 mm².

Devices are characterized with current-voltage (J-V) curves acquired under illumination from a Xe arc lamp with intensity calibrated to 1-sun with a NREL-calibrated Si reference cell with KG5 filter. EQE measurements are made with monochromated light from a tungsten halogen lamp chopped at 200 Hz. A Newport-calibrated Si diode was used to calibrate the system prior to taking EQE measurements. A spectral mismatch factor of ˜1.05 was calculated for the J-V measurements. A minimum of five devices are measured for each condition.

Hole only devices are fabricated on the same ITO coated glass substrates used for devices. 30 nm MoO₃ was grown on the substrates at 3×10⁻⁶ torr after sonication and plasma cleaning. 10 mg/ml of each organic salt in methanol was spun at 2000 rpm to form 45-55 nm films. 30 nm MoO₃ was grown on top of the organic salt and finally 80 nm Ag was grown using a mask to define the active area of 4.43 mm². J-V testing was performed in the dark by sweeping the voltage from −3.5 to 3.5 V. Device data was fit with the Mott-Gurney equation (Eq. 1) for space charge limited current (SCLC) to extract the hole mobility after confirming symmetric J-V behavior (single carrier device and not a diode) in both positive and negative sweeps.

$$J = \frac{9}{8} ε μ \frac{{v}^{2}}{{d}^{3}} \qquad Eq . 1$$

The SCLC regime was identified by the linear region described by J vs V², where ε is the dielectric constant of the organic salt approximated by the product of the permittivity of free space and the squared index of refraction of the organic salt, and d is the thickness of the organic salt film.

Transient photovoltage measurements are made to assess carrier lifetime by exciting devices with a Stradus 785 nm laser pulsed for 1 μs with a 500 μs period by an Agilent 80 MHz Function/Arbitrary Waveform Generator. The voltage decay was measured with an Agilent DSO-X 3032A Oscilloscope at 1 MΩ impedance and fitted with an exponential decay equation (Eq. 2), where V is the measured potential, t is the time, V₀ is the baseline potential, A is the pulse amplitude, and Tₕ is the carrier lifetime.

$$V = A {e}^{( \frac{- t}{{τ}_{h}} )} + {V}_{0} \qquad Eq . 2$$

Devices are biased with a white light so that V₀ was equal to the open circuit voltage and no net current flowed through the devices.

Thin film transmission data was collected for organic salt films spun from 10 mg/mL solutions onto cleaned unpatterned ITO coated glass substrates. A PerkinElmer UV-Vis spectrometer was used to make transmission measurements of the films. The reference slot was empty for solid-state thin film measurements. For solution measurements, organic salts at 10 μM in methanol are loaded into a borosilicate glass cuvette and placed in the sample slot of the spectrometer. Pure methanol in a second cuvette was placed in the reference slot. Transmission data was collected to obtain the absorption as 100-T (%). Photoluminescence measurements are made with a Photon Technology International fluorometer on 10 μM solutions of each salt.

Error bars represent the standard error calculated from experimental uncertainty in measurement techniques and variation in measured variables.

The mass and charge of each of the four anionic heptamethines are verified with a high mass resolution ultra high-performance liquid chromatography mass spectrometry (UHPLC-MS) system, the Waters Xevo G2-XS QTof. Salts are dissolved in MeOH at 1 μM. An injection volume of 10 μL was used with pure MeOH as the eluent. Background scans with MeOH are run before and after each organic salt sample. Peak signals from the chromatography column are observed at approximately two minutes, and are integrated to yield the mass-to-charge signals.

Computational: EQE can be broken into five component efficiencies shown in Eq. 3, where IQE is the internal quantum efficiency, η_{A} is the absorption efficiency, η_{ED} is the exciton diffusion efficiency, nor is the charge transfer efficiency, η_{DS} is the charge dissociation efficiency, and η_{CC} is the charge collection efficiency.

$$EQE = IQE {η}_{A} = {η}_{A} {η}_{ED} {η}_{CT} {η}_{DS} {η}_{CC} \qquad Eq . 3$$

To model PV devices, η_{CT} and η_{DS} are assumed to equal unity for a donor-acceptor interface with sufficient energetic offset to transfer charge and dissociate excitons into free charge carriers. Transfer matrix optical modeling was used to calculate the electric field and absorption profile (η_{A}) in PV devices based on measured optical indices of refraction. The charge collection efficiency equation (Eq. 4) was used to describe charge collection losses in the organic salt and C₆₀ layers, where d is the layer thickness of interest and L_{CC} is the charge collection length.

$${η}_{CC} = ( \frac{{L}_{CC}}{d} ) ( 1 - {e}^{( \frac{- d}{{L}_{CC}} )} ) \qquad Eq . 4$$

Exciton diffusion lengths (L_{ED,D}) for each organic salt are calculated with a nonlinear regression fit of the squared standard error for the difference between measured and calculated EQE. Devices with the thinnest organic salt layer are fitted for L_{ED,D} and the exciton diffusion length of C₆₀ (L_{ED,A}) with a C₆₀ charge collection length (L_{CC,A}) of 100 nm. Charge collection losses from the organic salt layer are not included in this initial model as L_{CC}>>L_{ED} for most organic materials. All other devices are fit with a fixed L_{ED,A} and L_{CC,A}, and a variable L_{ED,D} to reduce or prevent artificial shortening of L_{ED,A} as a result of organic salt charge collection losses in the C₆₀ absorption regime.

The calculated external quantum efficiency, EQE_{fixed L}_{_{ED,A}}, was used to modify the charge collection equation to form Eq. 5 and fit the experimental EQE at 440 nm for the organic salt charge collection length (L_{CC,D}) as a function of organic salt thickness.

$$EQE = {EQE}_{fixed {L}_{ED , A}} ( \frac{{L}_{CC}}{d} ) ( 1 - {e}^{( \frac{- d}{{L}_{CC}} )} ) \qquad Eq . 5$$

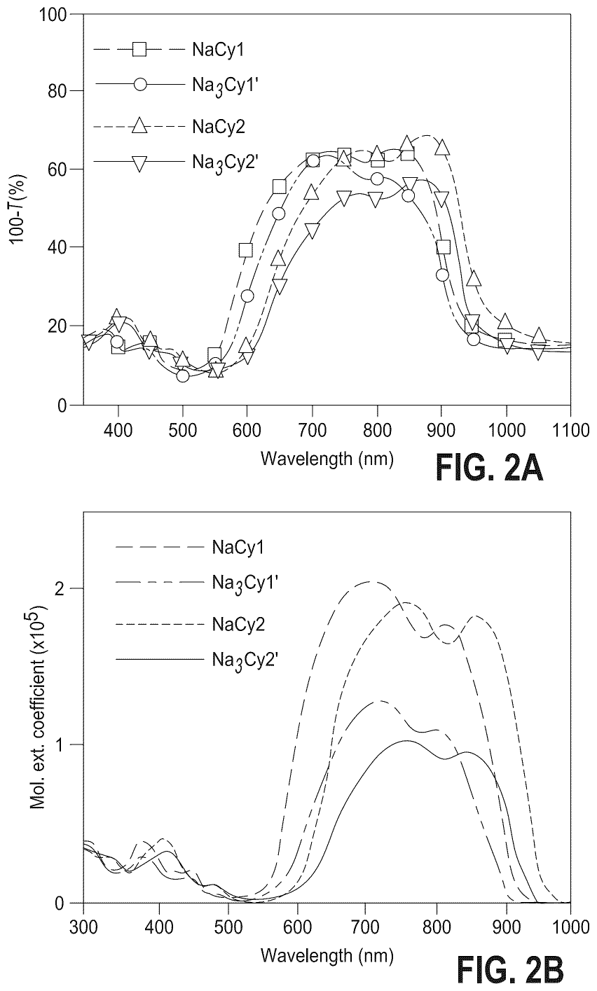

This wavelength was selected as the peak C₆₀ EQE with reduced or minimal but similar absorption by all four organic salts (FIGS. 2A-2B).

### RESULTS AND DISCUSSION

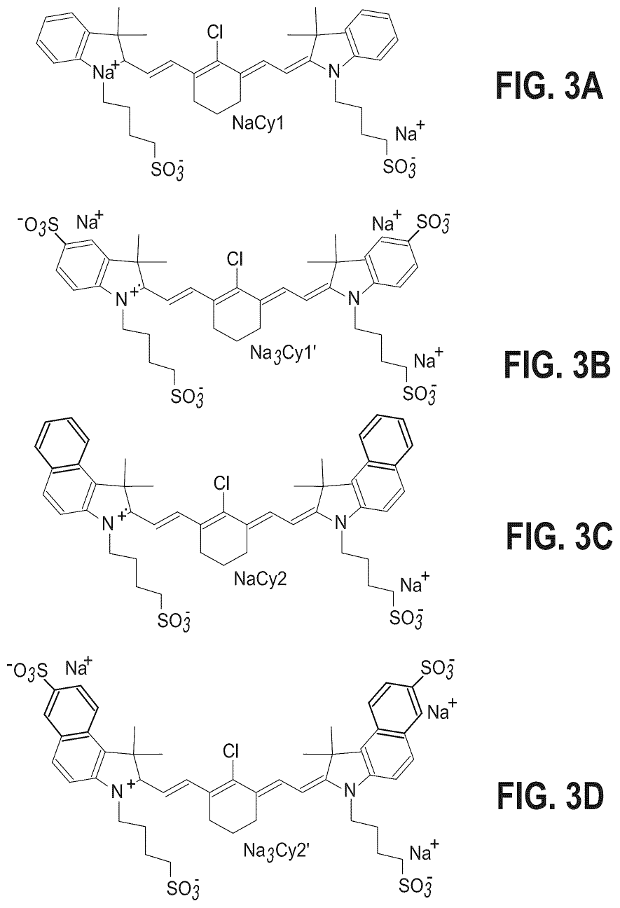

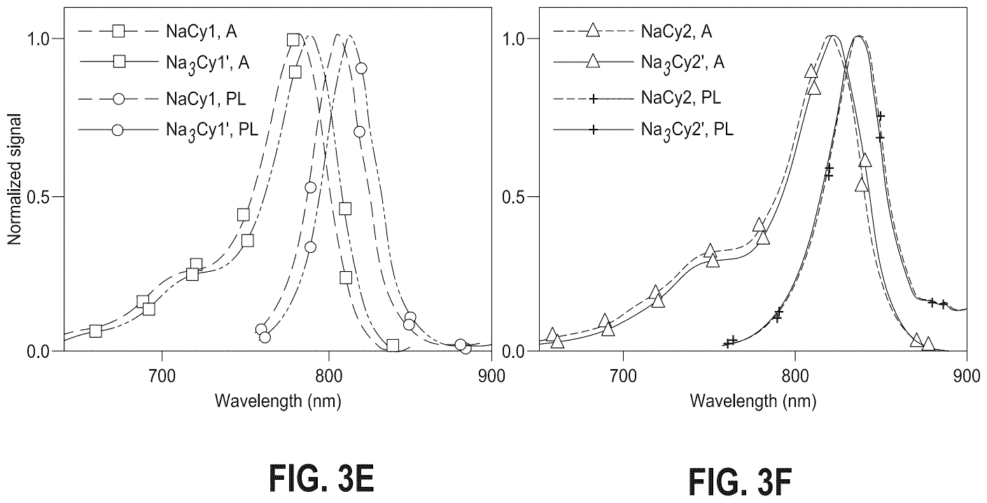

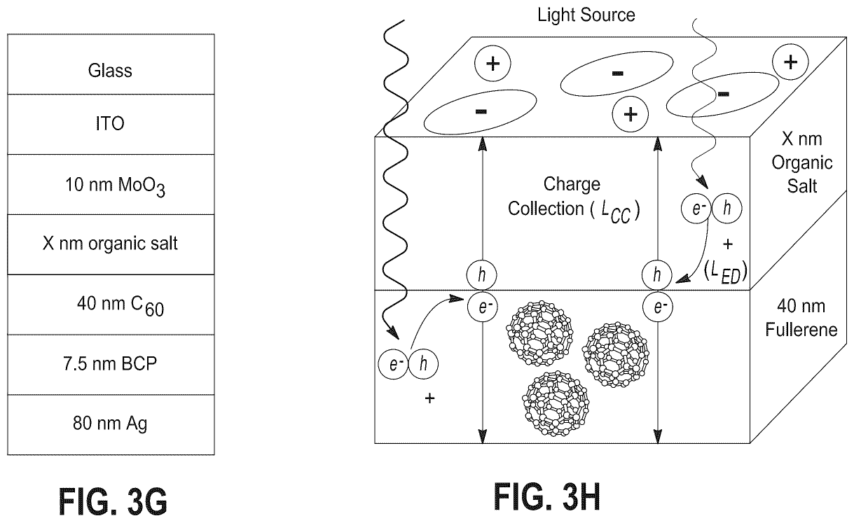

Device characterization: Four organic salts consisting of an anionic heptamethine chromophore paired with sodium counterions are selected for this example (FIGS. 3A-3D). All four salts absorb and emit light selectively in the NIR (FIGS. 3E-3F), and are labeled as NaCy1, Na₃Cy1′, NaCy2, and NaCy2′, with the prime designation indicating two additional sulfonate groups on the chromophore. The salts vary in either 1) end group conjugation (benzyl vs. naphthyl), NaCy1 to NaCy2 and Na₃Cy1′ to Na₃Cy2′, or 2) in total charge character on the chromophore (−1 with 1 paired cation vs. −3 with 3 paired cations for every anion), NaCy1 to Na₃Cy1′ and NaCy2 to Na₃Cy2′, which allows for the effects of these physical characteristics to be isolated.

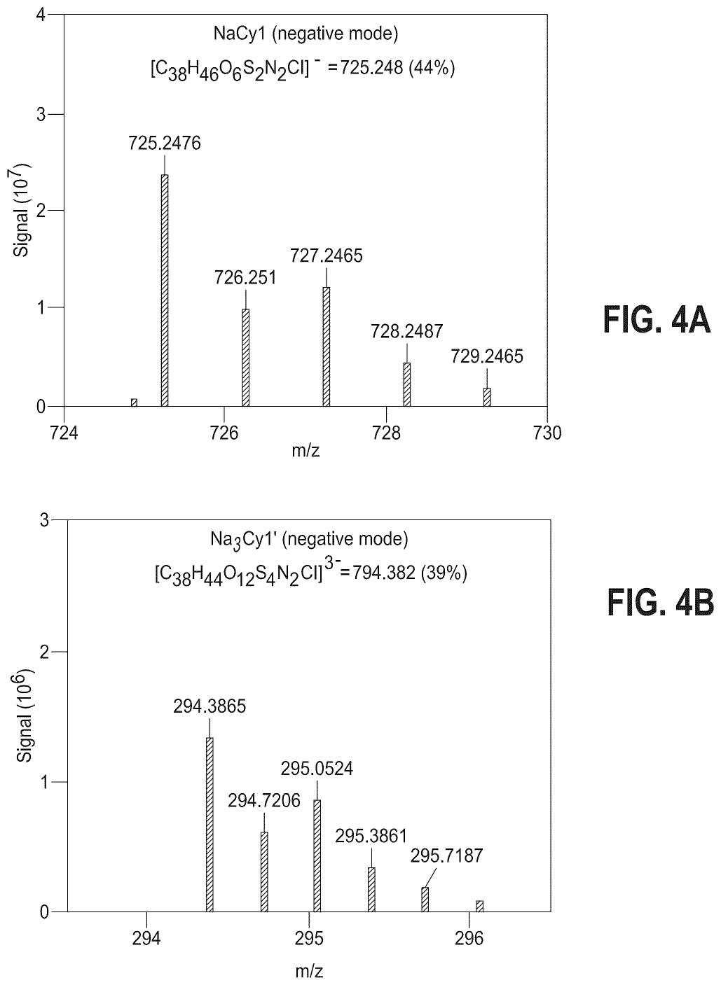

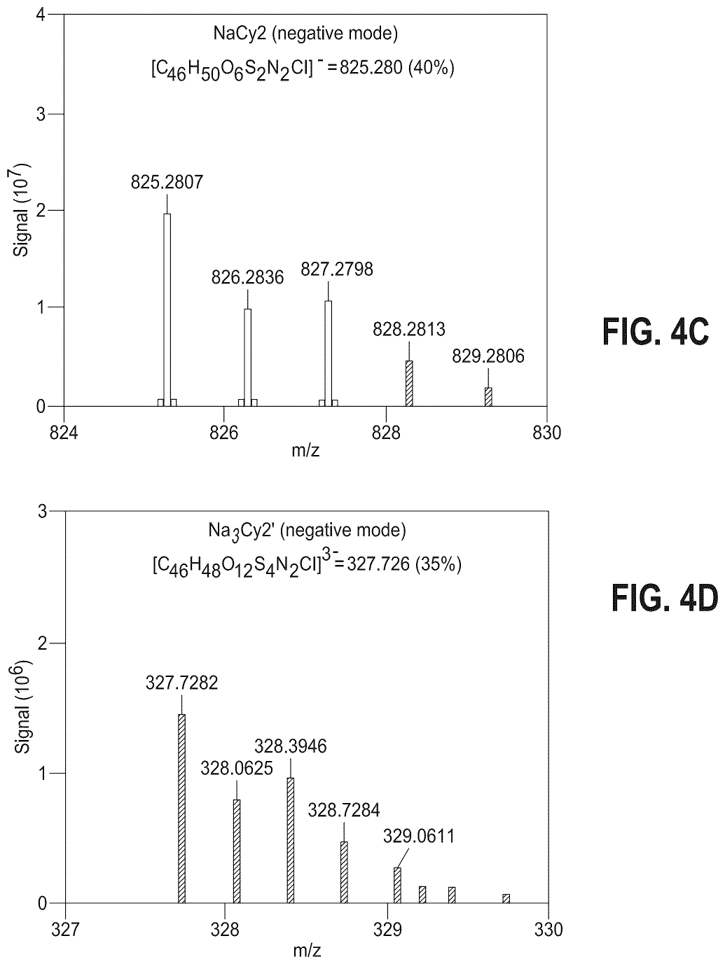

Single heterojunction bilayer devices are fabricated with each donor salt at various thicknesses paired with 40 nm C₆₀ as the acceptor (FIG. 3G). The mass and net charge of the salts are verified with UHPLC-MS (FIGS. 4A-4D). The selective absorption of the salts in the NIR and C₆₀ in the ultra-violet (UV) and short visible (VIS) (<600 nm) creates two distinct regions for photocurrent generation. This process is illustrated in FIG. 3H, where NIR light absorbed by the salts creates an excited state electron-hole pair (exciton) that diffuses to the salt-C₆₀ interface. The electron transfers to C₆₀ and the energetic offset between the lowest unoccupied molecular orbital (LUMO) of the salt and C₆₀ overcomes the exciton binding energy to produce two free charge carriers, which move through the C₆₀ (electron) or organic salt (hole) to the electrodes. Photocurrent generation from C₆₀ undergoes an analogous process with UV-VIS light, where the dissociated exciton from Co creates a hole that must transport similarly through the donor salt layer.

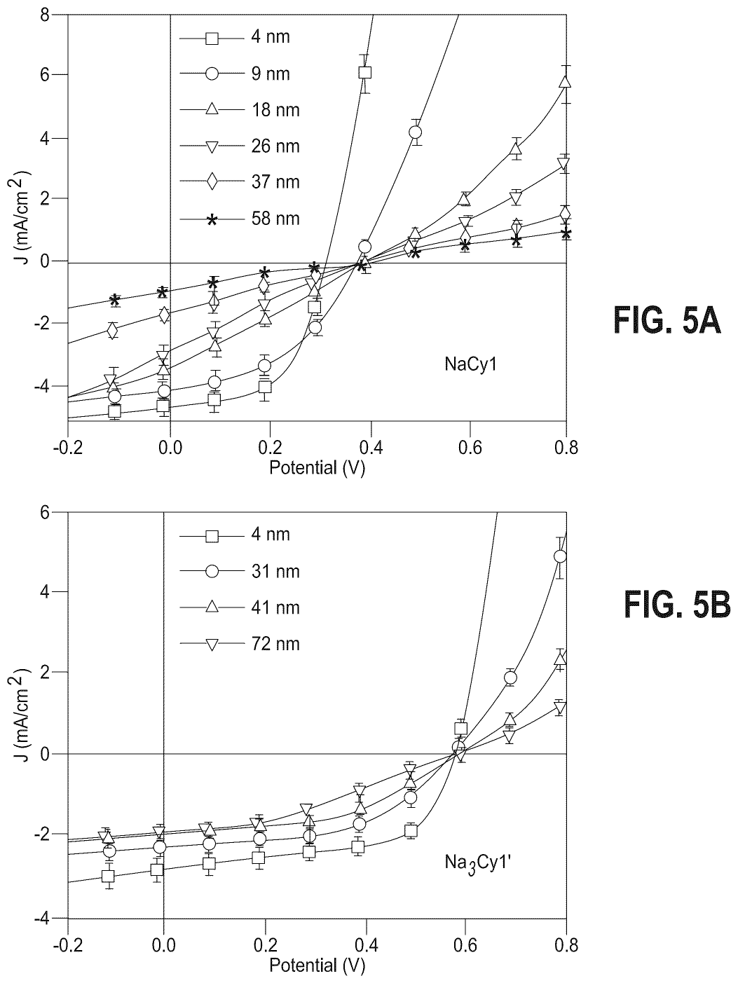

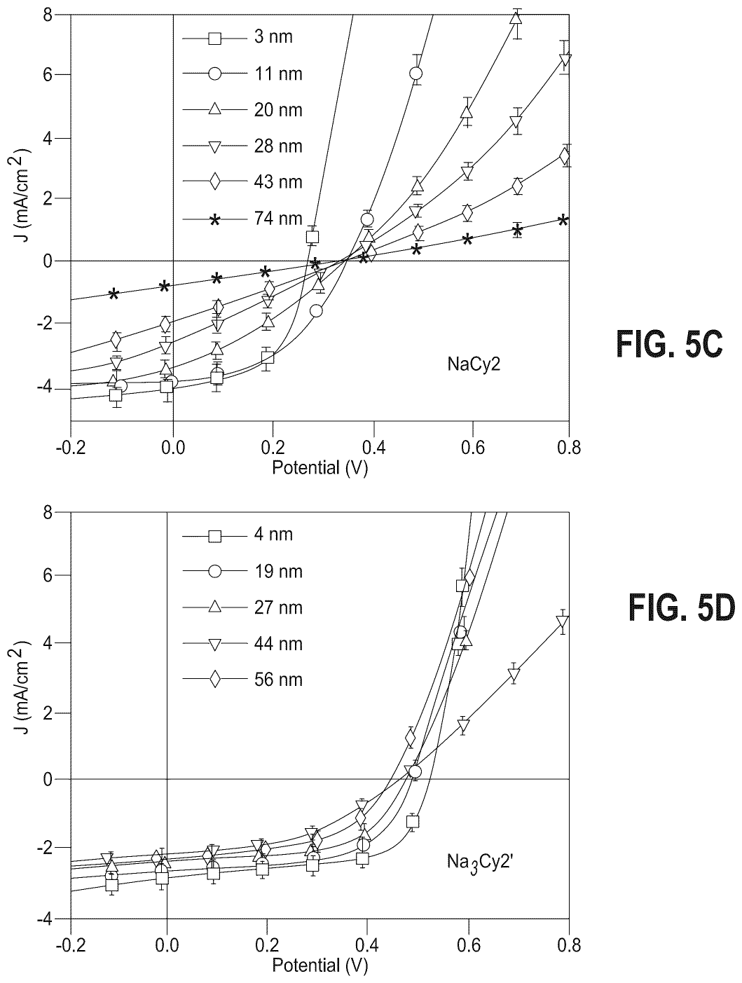

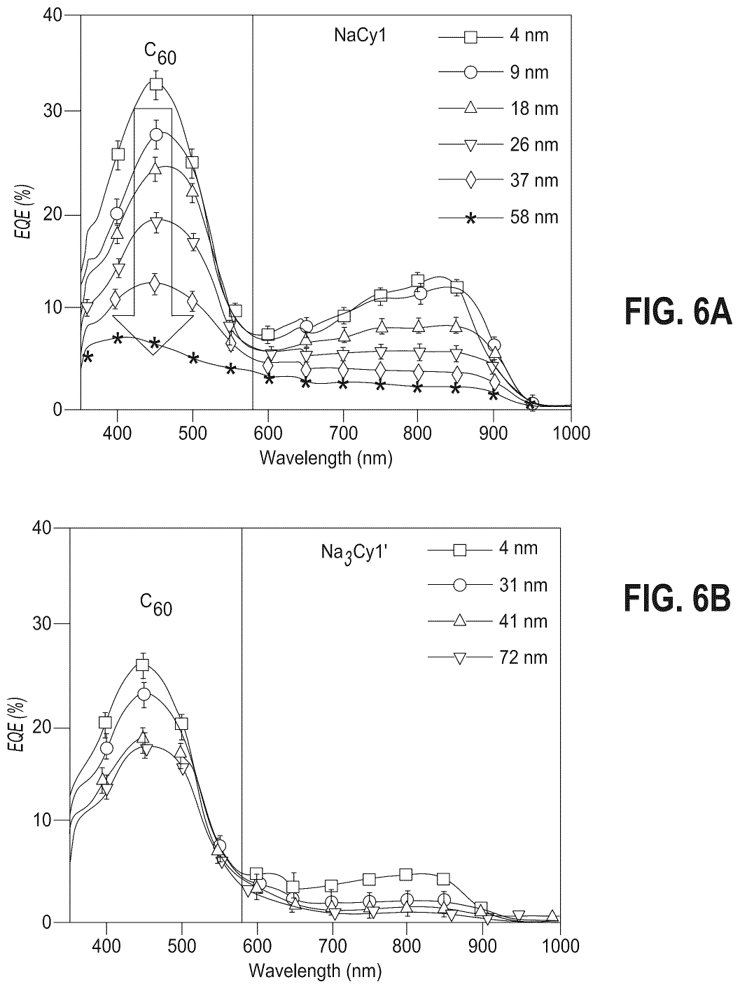

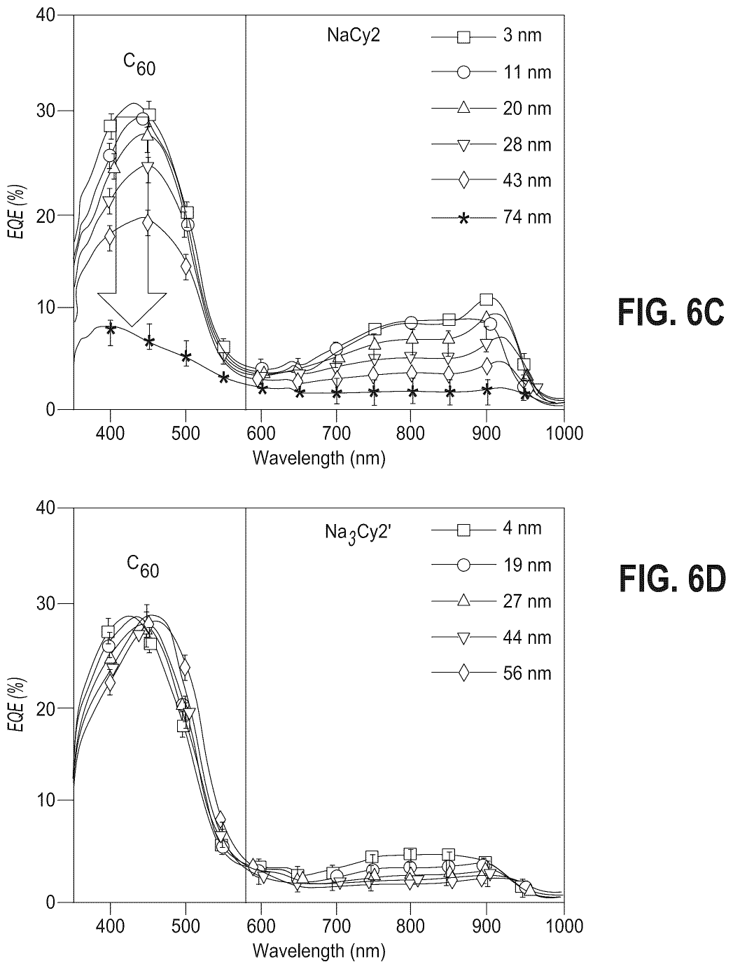

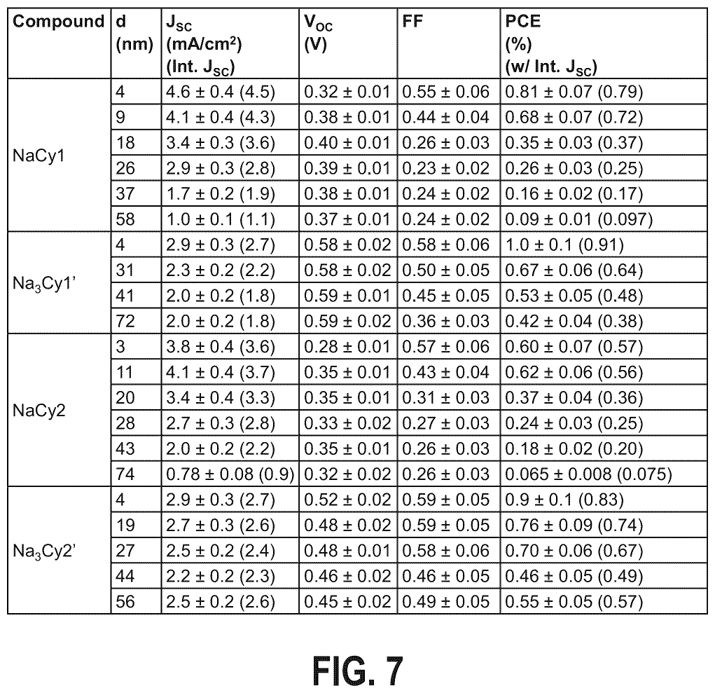

This example demonstrates these processes in PV devices via thickness-dependent J-V curves (FIGS. 5A-5D) and EQE data (FIGS. 6A-6D) for each salt. The open circuit voltage (Voc) of the devices is controlled by the interface gap between the salt HOMO and C₆₀ LUMO and is independent of donor thickness with the exception of devices with less than 5 nm of organic salt. This suggests interface energetics between the salt and C₆₀ are essentially constant (no band bending). Thickness independent interface energetics indicates a consistent LUMO-LUMO offset for carrier generation. The voltage increases with increased charge character on the chromophore, from 0.4 V to 0.6 V for NaCy1 to Na₃Cy1′ and 0.35 V to 0.5 V for NaCy2 to Na₃Cy2′ (FIG. 7). This is notable as reduced or minimal changes in the optical bandgap are observed with increased charge character either in the solution state (FIG. 3E-3F) or the solid state (FIGS. 2A-2B) and suggests that either the bandgap is shifted down to create a larger interface gap between the organic salt HOMO and C₆₀ LUMO, or there are fewer energetic losses. The voltage decreases with increased conjugation from Cy1 to Cy2 (0.4 to 0.35 V and 0.6 to 0.5 V). This is expected as extra conjugation narrows the bandgap, likely between the salt and C₆₀ are essentially constant (no band bending). Thickness independent interface energetics indicates a consistent LUMO-LUMO offset for carrier generation. The voltage increases with increased charge character on the chromophore, from 0.4 V to 0.6 V for NaCy1 to Na₃Cy1′ and 0.35 V to 0.5 V for NaCy2 to Na₃Cy2′ (FIG. 7). This is notable as reduced or minimal changes in the optical bandgap are observed with increased charge character either in the solution state (FIG. 3E-3F) or the solid state (FIGS. 2A-2B) and suggests that either the bandgap is shifted down to create a larger interface gap between the organic salt HOMO and C₆₀ LUMO, or there are fewer energetic losses. The voltage decreases with increased conjugation from Cy1 to Cy2 (0.4 to 0.35 V and 0.6 to 0.5 V). This is expected as extra conjugation narrows the bandgap, likely 4A-4D), which is related to the J_{sc} with Eq. 6, where q is the elementary charge and S(λ) is the solar spectrum.

$${J}_{SC} = q \int EQE ( λ ) S ( λ ) d λ \qquad Eq . 6$$

In general, J_{sc} values measured from J-V align well with integrated JSC from EQE, validating the trends observed for the four organic salts. The separate absorption domains of C₆₀ (UV and short VIS) and organic salt (NIR) are marked in FIGS. 6A-6D to delineate the origin of photon absorption and exciton formation. Examining the organic salt region, singly charged chromophores demonstrate higher peak EQEs (at low thicknesses) than salts with increased charge character on the chromophore at similar thicknesses. Molecular extinction coefficients are slightly stronger for organic salts with singly charged chromophores (FIG. 2B), and a combination of increased absorption and larger exciton diffusion length explains the higher NIR EQE. All four salts demonstrate significant roll-off in the NIR with increased thickness, indicating overarching limitations from exciton diffusion, charge collection, or both. Turning to the C₆₀ domain, two starkly different trends are observed between the singly and triply charged anions. NaCy1 and NaCy2 demonstrate significant drop off in C₆₀ EQE as the donor salt thickness increases while Na₃Cy1′ and Na₃Cy2′ show little change in the C₆₀ EQE. Given the constant C₆₀ thickness, the lone variable from Eq. 3 changing with organic salt thickness is the charge collection of the hole moving through the salt layer, described by Eq. 4. The sharp decay in photocurrent generated from C₆₀ suggests that organic salts with singly charged chromophores possess much shorter charge collection lengths than those with a −3 net charge. The EQE in the C₆₀ region for Na₃Cy1′ and Na₃Cy2′ shows high relative efficiencies at salt thickness greater than 50 nm, which is in agreement with the J_{sc} values discussed earlier.

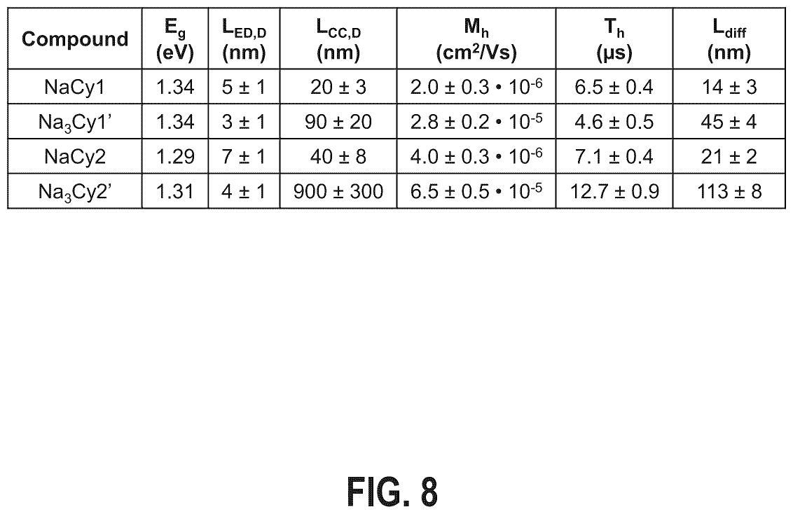

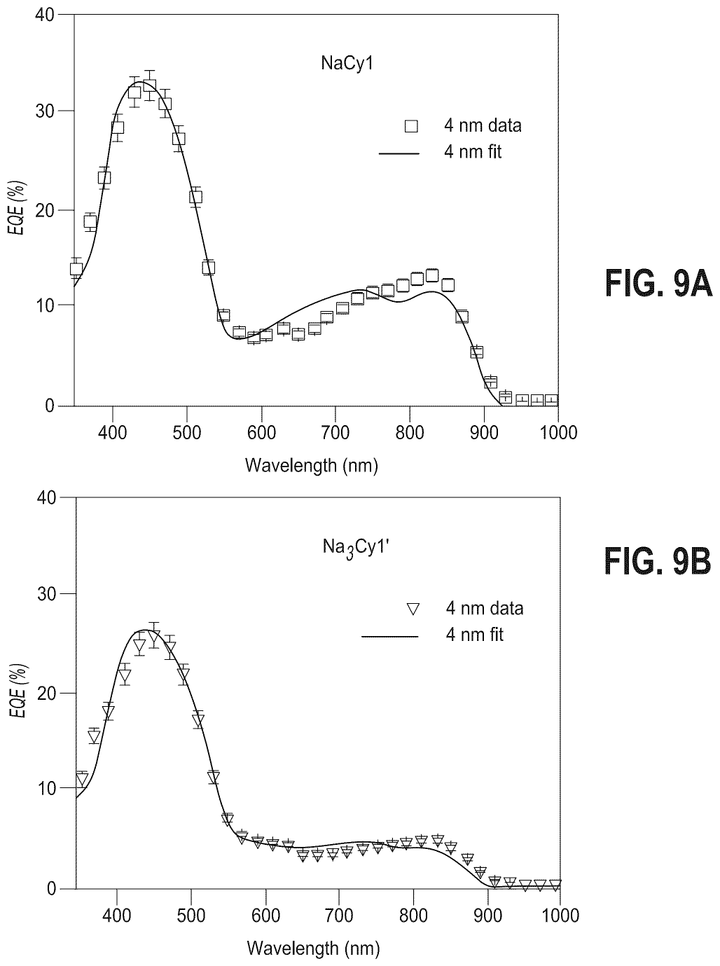

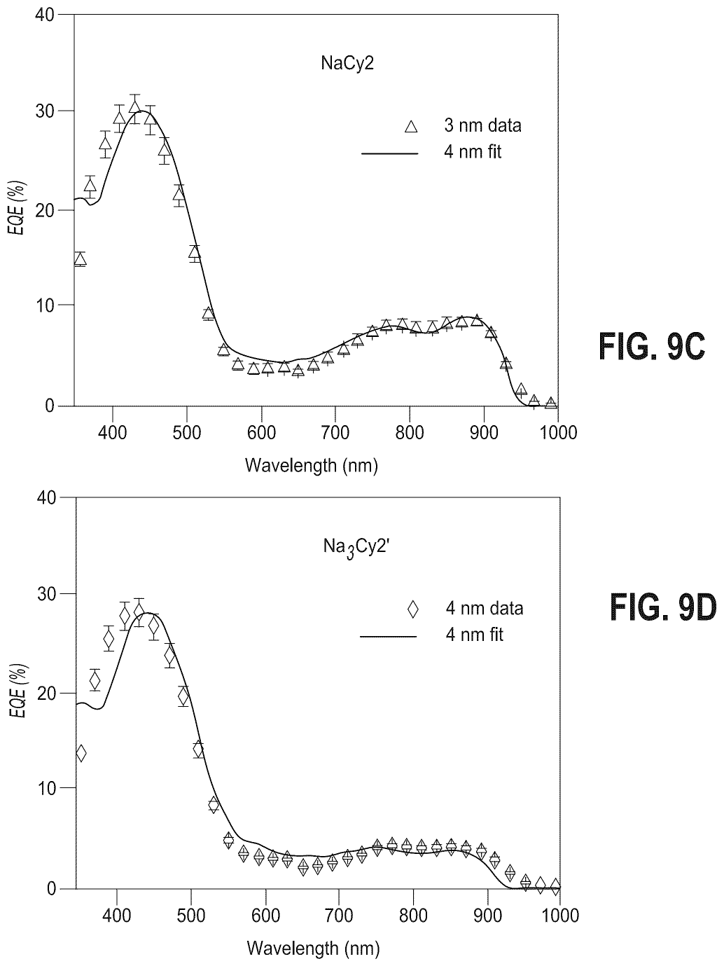

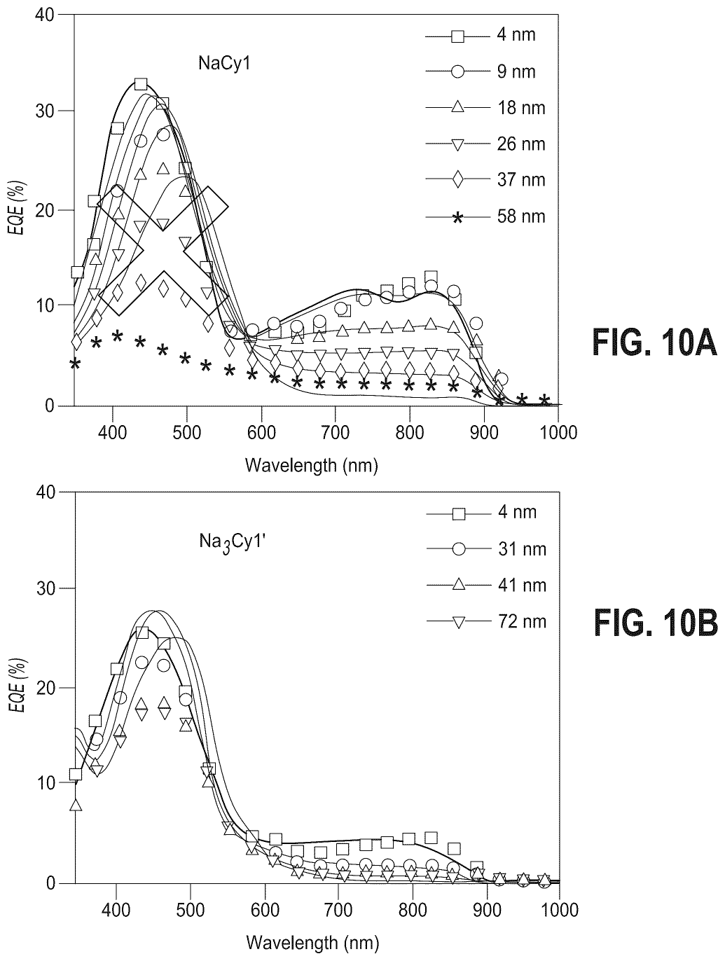

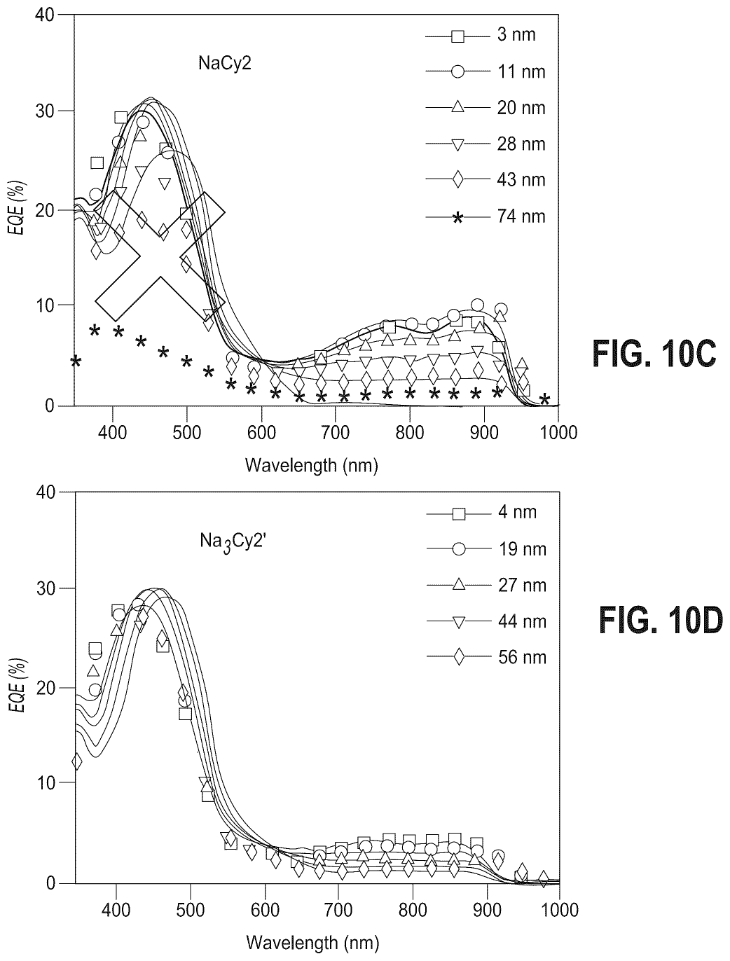

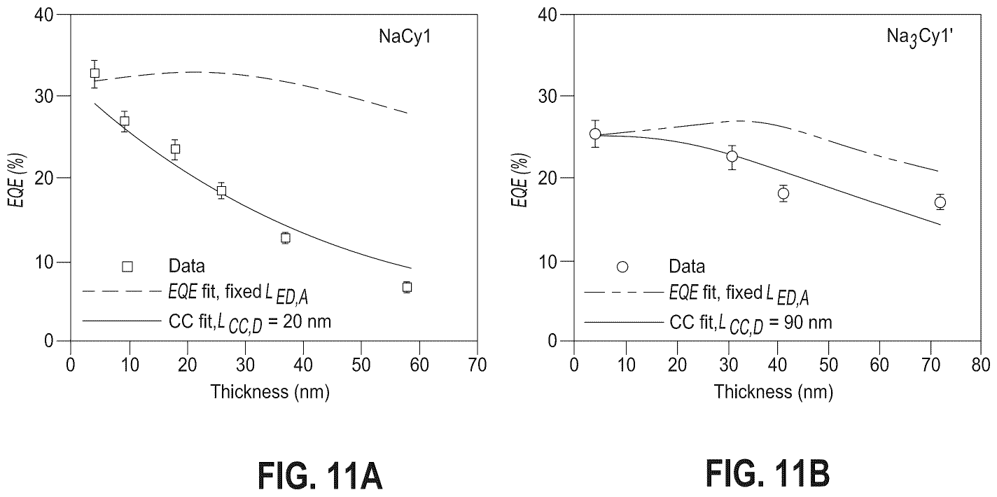

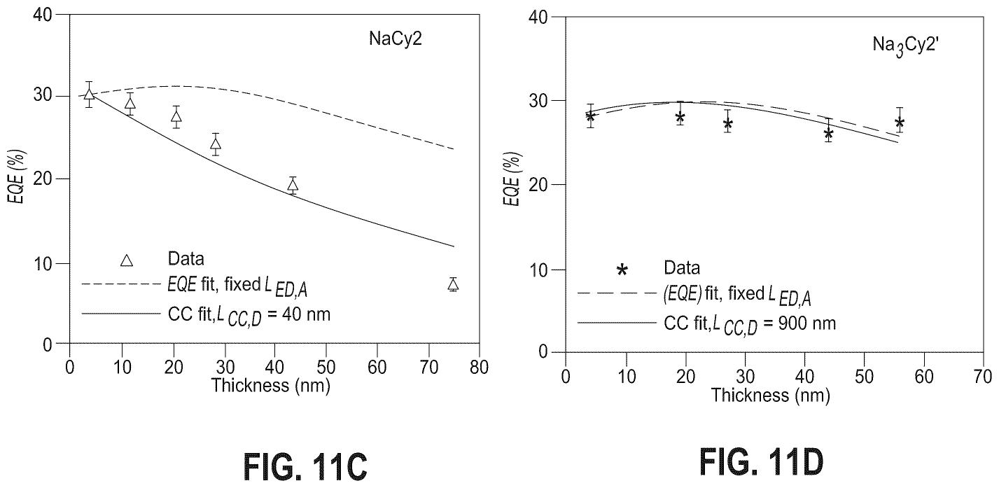

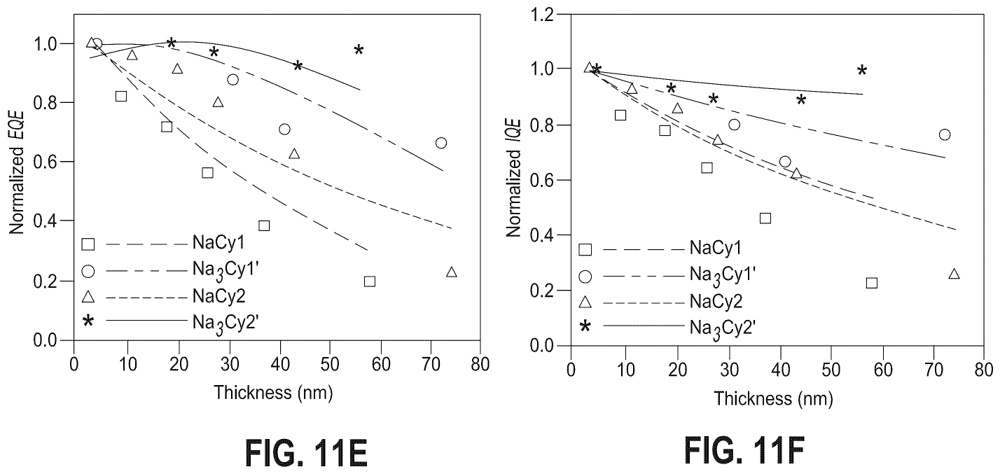

Charge transfer analysis: To further understand the charge transfer capabilities of the four organic salts, transfer matrix optical modeling was used to first extract exciton diffusion lengths (L_{ED,D} and L_{ED,A}) and then charge collection lengths for each salt (L_{CC,D}), which are included in FIG. 8. Initial fits for exciton diffusion lengths are shown in FIGS. 9A-9D, where the model is in agreement with experimental EQE data. Increased charge character on the chromophore leads to decreased exciton diffusion lengths as expected from analysis of the NIR region EQE discussed above. EQE modeling with a fixed L_{ED,A} shows a clear difference between singly and triply charged anionic cyanines (FIGS. 9A-10D). Devices with reduced or minimal charge collection losses are fitted well by the model, as exciton diffusion is the primary limitation. This is the case for Na₃Cy1′ and Na₃Cy2′, shown in FIGS. 10B and 9D and as the dashed lines in FIGS. 11B and 11D, where the model accurately captures the experimental EQE thickness dependent trends. For NaCy1 and NaCy2, large charge collection losses cause the C₆₀ region EQE to drop off with organic salt thickness and the model cannot account for the losses with a fixed L_{ED,A} (FIGS. 10A and 10C, and dashed lines in FIGS. 11A and 11C).

Eq. 5 was used to fit experimental EQE at 440 nm for organic salt charge collection lengths, and the resulting fits are shown as the solid line in FIGS. 11A-11D. As expected from analysis of the J-V and EQE data, organic salts with increased charge character possess significantly longer charge collection lengths (FIG. 8). To examine the trends from a different perspective, normalized EQE and IQE (calculated with Eq. 3 from modeled absorption) data and fits are shown in FIGS. 11E-11F. The triply charged anionic cyanines still demonstrate surprisingly distinct charge transfer behavior, which is especially evident for the thicker organic salt devices.

Charge collection length analysis: Charge collection lengths are determined by the carrier mobility and lifetime for carriers moving through the organic salt films. In the donor, hole transfer is driven by two mechanisms, diffusion of holes due to the concentration gradient from the organic salt-C₆₀ interface where excitons are dissociated to the MoO₃-organic salt interface where holes are extracted to the electrodes, and by carrier drift due to the built-in electric field present in the device. Carrier drift lengths are inversely proportional to the depletion width, the size of which is associated with the amount of band bending at the donor-acceptor interface. Significant band bending indicates a large region of linearly decreasing (or increasing) voltage across the donor-acceptor heterojunction and results in the V_{OC} varying strongly with layer thickness. As discussed above, the V_{OC} for all four salts is largely independent of organic salt thickness for d>5 nm, indicating that the depletion widths are likely small (similar to other reports) and charge transport is carrier diffusion limited. Carrier diffusion lengths (L_{Diff}) are related to the carrier mobility and lifetime by Eq. 7 with the Boltzmann constant (k_{B}), temperature (T), and dimensionality factor (Z, equal to 6 for three dimensional diffusion).

$${L}_{Diff} = \sqrt{\frac{Z {k}_{B} T {μ}_{h} {τ}_{h}}{q}} \qquad Eq . 7$$

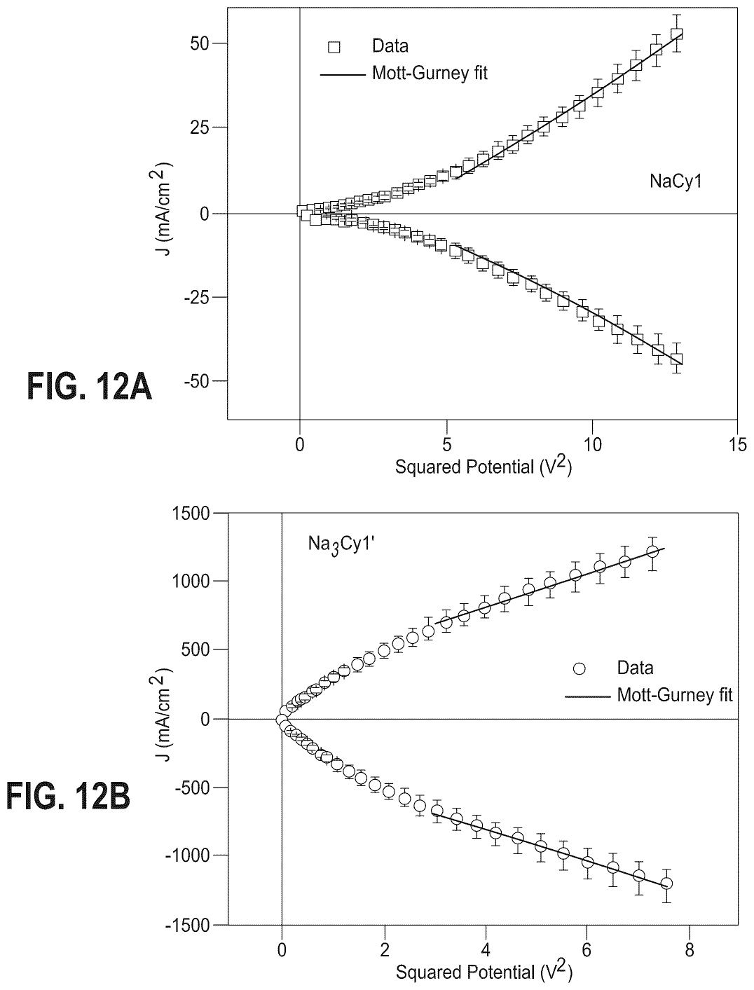

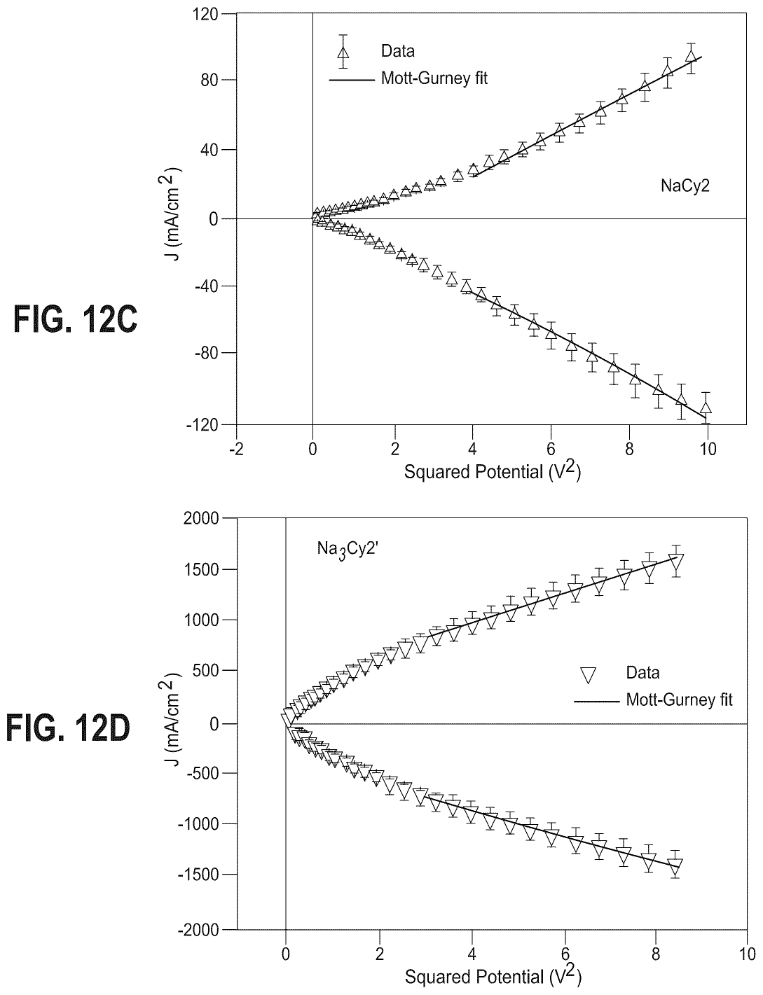

Hole only devices, verified as single carrier devices by the symmetric J-V curves which do not show a built-in potential (VOC≠0) or diode formation (unsymmetrical J-V properties for forward and reverse bias), fitted with the Mott-Gurney equation for SCLC (FIGS. 12A-12D) allow for un to be calculated from the slope of the region where J α V². Current generated at low potentials are likely ohmic in nature where J α V, indicating that a space charge region has not yet been formed. Hole mobilities (FIG. 8) increase by over an order of magnitude from NaCy1 to Na₃Cy1′ and NaCy2 to NaCy2′, suggesting that increased negative charge character on the cyanine improves charge transfer through organic salt films. The hole mobility trends are in agreement with the calculated L_{CC} and device performance in EQE.

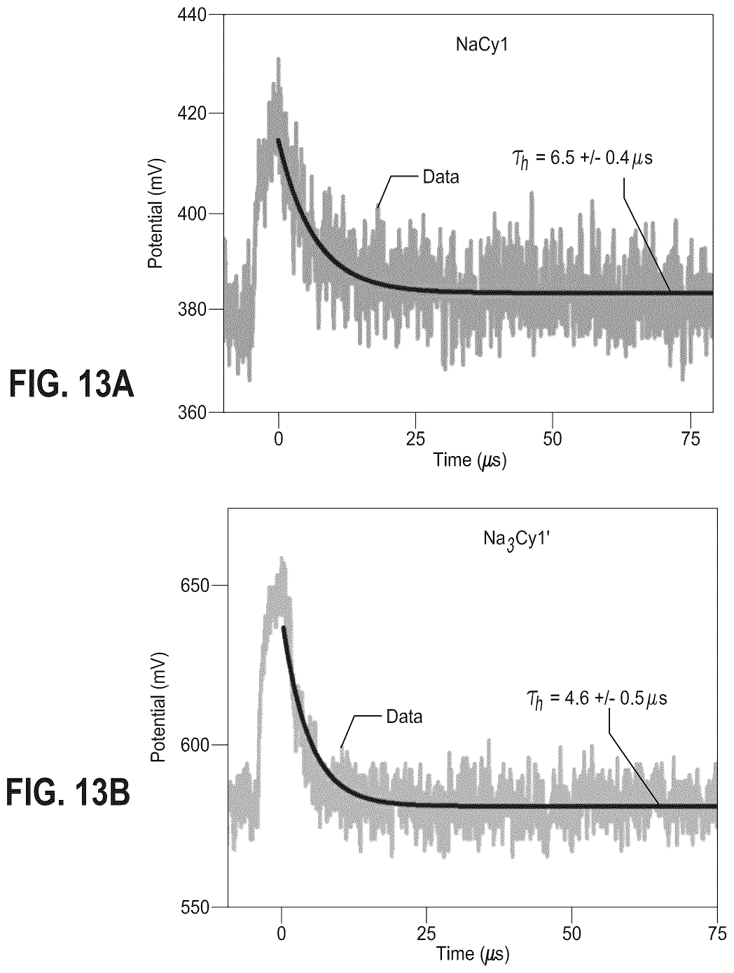

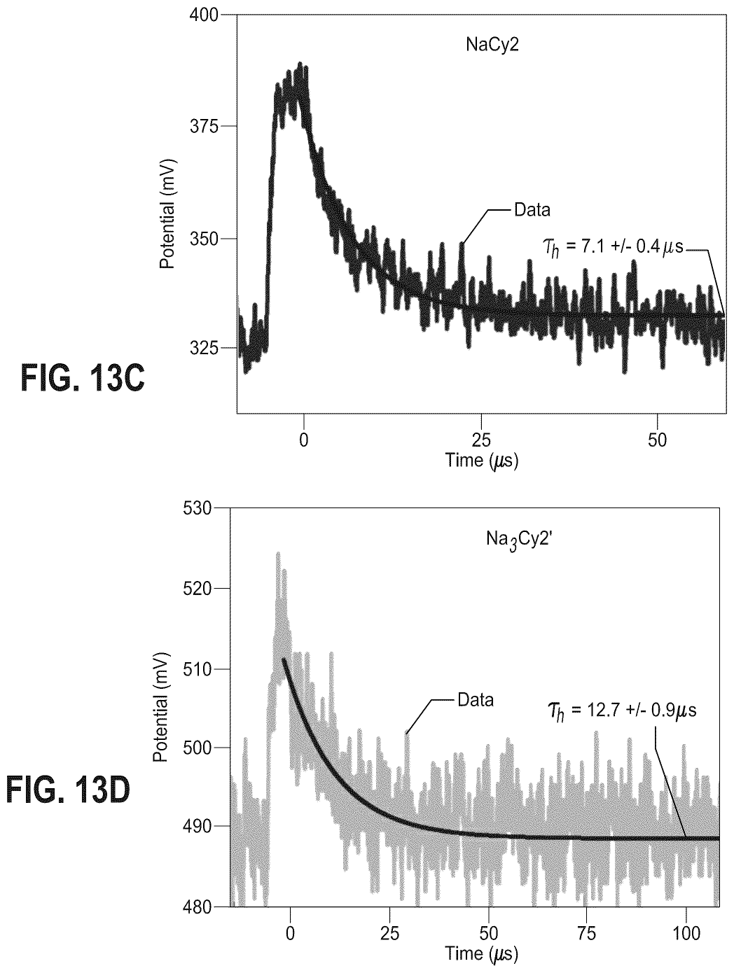

To complete the charge collection characterization of the organic salts, transient photovoltage measurements are made for each salt under V_{OC} to assess the carrier lifetime. Data fitted with an exponential decay function is shown in FIGS. 13A-13D and the extracted hole lifetimes, Tₕ, are reported in FIG. 8. No clear correlation is found in carrier lifetimes related to charge character or conjugation, so that the L_{CC} is largely dictated by changes in the mobility. However, Na₃Cy2′ possesses the largest Tₕ, which combined with the highest mobility explains the stable C₆₀ EQE past 50 nm and the large L_{CC}. L_{Diff} calculated from the measured mobility and lifetime is reported in FIG. 8. In comparison to L_{CC}, L_{Diff} shows excellent agreement with the overall trend between organic salts in regard to the increased charge character improving charge transfer. Conceptually, enhanced hole transfer could occur via the anionic chromophores, where increased negative charge character stabilizes the positively charged hole. Alternatively, the increased presence of cationic counterions could provide a pathway of static positive charges that accelerate hole movement via charge repulsion. Our analysis of the charge collection lengths shows improved carrier mobility drives efficient charge transfer in organic salt films comprised of triply charged anionic heptamethines.

### CONCLUSIONS

This example demonstrates a series of anionic salt donor OPVs. Through fabrication and analysis of organic salt thickness dependent devices with four anionic heptamethines the example shows a surprising change in charge transport based on the charge character of the salt that is consistent with variation in conjugation. Triply charged chromophores possess orders of magnitude higher carrier mobilities than singly charged chromophores yielding excellent charge collection for thick (>50 nm) organic salt films, while coming at the cost of reducing the exciton diffusion length slightly. Improved mobility leads to devices with sustained acceptor and donor EQE for thicker salt layers, higher photocurrent, and better device performance. This fundamental understanding of how to improve charge transport is important to realizing organic salts as high efficiency TPV materials. An important limiting factor for organic salts moving forward is the short exciton diffusion lengths, which could be enhanced by counterion selection. Additionally, this example suggests that there could be similarly interesting effects of total charge in cationic cyanines. Ultimately, a combination of charge transfer optimization via chromophore charge character and counterion selection for optimizing exciton diffusion length and orbital energy levels could produce exciting new organic salts for a variety of photovoltaic and optoelectronic applications.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A photovoltaic device comprising:
a first electrode;
a second electrode; and
a photoactive layer between the first electrode and the second electrode, the photoactive layer including,
a first organic salt, the first organic salt including,
a photoactive ion having a first valence selected from the group consisting of: 1+, 2+, 3+, 4+, 5+, 6+, 7+, 8+, 1−, 2−, 3−, 4−, 5−, 6−, 7−, or 8−, and
a counterion having a second valence selected from the group consisting of: 1+, 2+, 3+, 4+, 5+, 6+, 7+, 8+, 2−, 3−, 4−, 5−, 6−, 7−, or 8−, wherein
a sum of a magnitude of the first valence and a magnitude of the second valence is greater than or equal to 3, and
a net charge of the first organic salt is zero.

2. The photovoltaic device of claim 1, wherein the sum of the magnitude of the first valence and the second valence is greater than or equal to 4.

3. The photovoltaic device of claim 1, wherein the photoactive ion is a photoactive cation and the counterion is an anion.

4. The photovoltaic device of claim 5, wherein the anion is a tetrel, a chalcogen, a halogen, a transition metal, organic anion, a tetrahedral anion, an octahedral anion, or any combination thereof.

5. The photovoltaic device of claim 1, wherein the photoactive ion is a photoactive anion and the counterion is a cation.

6. The photovoltaic device of claim 3, wherein the cation is an alkali metal, an alkaline earth metal, a transition metal, a triel, a tetral, a pnictogen, an organic cation, or any combination thereof.

7. The photovoltaic device of claim 1, wherein the photoactive ion is a polymethine cyanine salt.

8. The photovoltaic device of claim 1, wherein the first organic salt has an exciton diffusion length ranging from 10 nm to 300 nm.

9. The photovoltaic device of claim 1, wherein the first organic salt has a charge collection length ranging from 10 nm to 10,000 nm.

10. The photovoltaic device of claim 1, wherein the first organic salt has a bandgap of less than or equal to 2 eV.

11. The photovoltaic device of claim 1, wherein the entire device has an average visible transmittance (AVT) of greater than 50%.

12. The photovoltaic device of claim 1, wherein the device is opaque.

13. The photovoltaic device of claim 1, wherein the device has a power conversion efficiency of greater than 0.5%.

14. The photovoltaic device of claim 1, wherein the device has a maximum external quantum efficiency (EQE) of greater than or equal to 2%.

15. The photovoltaic device of claim 1, wherein the photoactive layer includes,
a donor layer, and
an acceptor layer.

16. The photovoltaic device of claim 15, wherein
the donor layer is neat, and
the acceptor layer is neat.

17. The photovoltaic device of claim 15, wherein the donor layer includes the first organic salt.

18. The photovoltaic device of claim 15, wherein the donor layer is amorphous.

19. The photovoltaic device of claim 15, wherein the donor layer is crystalline or nanocrystalline.

20. The photovoltaic device of claim 17, wherein the donor layer further includes a second organic salt.

21. The photovoltaic device of claim 20, wherein the second organic salt includes
a second photoactive ion having a third valence selected from the group consisting of: 1+, 2+, 3+, 4+, 5+, 6+, 7+, 8+, 1−, 2−, 3−, 4−, 5−, 6−, 7−, or 8−, and
a second counterion having a fourth valence selected from the group consisting of: 1+, 2+, 3+, 4+, 5+, 6+, 7+, 8+, 2−, 3−, 4−, 5−, 6−, 7−, or 8−, wherein
a sum of a magnitude of the third valence and a magnitude of the fourth valence is greater than or equal to 3, and
a net charge of the second organic salt is zero.

22. The photovoltaic device of claim 17, wherein the acceptor layer includes a fullerene.

23. The photovoltaic device of claim 17, wherein the acceptor layer includes a second organic salt.

24. The photovoltaic device of claim 23, wherein the second organic salt includes
a second photoactive ion having a third valence selected from the group consisting of: 1+, 2+, 3+, 4+, 5+, 6+, 7+, 8+, 1−, 2−, 3−, 4−, 5−, 6−, 7−, or 8− and
a second counterion having a fourth valence selected from the group consisting of: 1+, 2+, 3+, 4+, 5+, 6+, 7+, 8+, 2−, 3−, 4−, 5−, 6−, 7−, or 8− wherein
a sum of a magnitude of the third valence and a magnitude of the fourth valence is greater than or equal to 3, and
a net charge of the second organic salt is zero.

25. The photovoltaic device of claim 15, wherein
the donor layer defines a first thickness ranging from 5 nm to 200 nm.
the acceptor layer defines a second thickness ranging from 5 nm to 200 nm.

26. The photovoltaic device of claim 15, wherein
the donor layer has a peak absorption at a first wavelength of greater than or equal to 650 nm, and
the acceptor layer has a peak absorption at a second wavelength of greater than or equal to 650 nm.

27. The photovoltaic device of claim 1, wherein the device has a fill factor of greater than or equal to 0.45.

28. The photovoltaic device of claim 1, wherein the device has an absorption of greater than 50% at a wavelength of greater than or equal to 300 nm to less than or equal to 1,200 nm.

29. The photovoltaic device of claim 1, wherein the device has an open circuit voltage of greater than 50% of the excitonic voltage limit.

30. The photovoltaic device of claim 1, wherein the magnitude of the valence of the photoactive ion is greater than the magnitude of the counterion.

31. The photovoltaic device of claim 1, wherein the counterion is a photoactive ion.
